(19) United States
(12) Patent Application Publication
(10) Pub. No.: US 2025/0370075 A1
(43) Pub. Date: Dec. 4, 2025

(54) MAGNETIC RESONANCE IMAGING METHODS AND SYSTEMS

(71) Applicant: SHANGHAI UNITED IMAGING HEALTHCARE CO., LTD., Shanghai (CN)

(72) Inventors: Naijia LIU, Shanghai (CN); Jun YANG, Shanghai (CN); Zhenkui WANG, Shanghai (CN)

(73) Assignee: SHANGHAI UNITED IMAGING HEALTHCARE CO., LTD., Shanghai (CN)

(21) Appl. No.: 19/221,603

(22) Filed: May 29, 2025

(30) Foreign Application Priority Data
May 31, 2024 (CN) 202410705325.3
Jun. 6, 2024 (CN) 202410735100.2

(51) Int. Cl. G01R 33/48; G01R 33/561; G01R 33/565

(52) U.S. Cl. CPC G01R 33/4822; G01R 33/5619; G01R 33/56545

(57) ABSTRACT

An magnetic resonance imaging method and system is provided. The method includes: obtaining at least one first K-space dataset from a plurality of K-space datasets corresponding to a plurality of phases of an imaging object; for each of the at least one first K-space dataset, determining a target K-space dataset corresponding to the first K-space dataset by filling, based on at least one second K-space dataset, an undersampled region of the first K-space dataset; and generating a reconstructed image of the imaging object based on the target K-space dataset.

### CROSS REFERENCE TO RELATED APPLICATIONS

This application claims priority to Chinese Patent Application No. 202410735100.2, filed on Jun. 6, 2024, and Chinese application No. 202410705325.3 filed on May 31, 2024, the entire contents of each of which are incorporated herein by reference.

### TECHNICAL FIELD

The present disclosure relates to the field of medical imaging technology, and in particular, to a magnetic resonance imaging (MRI) method and system.

### BACKGROUND

In a process of magnetic resonance dynamic imaging, to utilize information of temporal and spatial dimensions for image reconstruction, interleaved K-space sampling trajectories are usually used. In addition, to pursue a higher temporal and spatial resolution, each K-space sampling trajectory is generally highly sparse. However, highly sparse sampling affects quality of an image obtained by subsequent reconstruction.

Image reconstruction for magnetic resonance dynamic imaging in the related art is based on a reconstruction manner of parallel imaging, e.g., sensitivity encoding (SENSE) and generalized autocalibrating partial parallel acquisition (GRAPPA), etc., However, in the case of requiring a high temporal and spatial resolution, images generated by the image reconstruction manners in the related art will have acceleration artifacts, which results in a low image quality.

Therefore, it is desirable to provide a magnetic resonance imaging method and system for obtaining magnetic resonance images with high quality using undersampled K-space data.

### SUMMARY

One or more embodiments of the present disclosure provide a magnetic resonance imaging method. The method includes: obtaining at least one first K-space dataset from a plurality of K-space datasets corresponding to a plurality of phases of an imaging object, the at least one first K-space dataset being undersampled, and each of the plurality of K-space datasets corresponding to one of the plurality of phases; for each of the at least one first K-space dataset, determining a target K-space dataset corresponding to the first K-space dataset by filling, based on at least one second K-space dataset, an undersampled region of the first K-space dataset, the at least one second K-space dataset being from the plurality of K-space datasets and corresponding to a different phase from the first K-space dataset; and generating a reconstructed image of the imaging object based on the target K-space dataset.

In some embodiments, at least two first K-space datasets are obtained from the plurality of K-space datasets of the imaging object; and for each of the at least one first K-space dataset, determining the target K-space dataset corresponding to the first K-space dataset by filling, based on the at least one second K-space dataset, the undersampled region of the first K-space dataset includes: arranging the at least two first K-space datasets in a preset order; determining the target K-space dataset corresponding to each of the at least two first K-space datasets by processing, in the preset order, the at least two first K-space datasets.

In some embodiments, the undersampled region of the first K-space dataset includes a plurality of undersampled sub-regions; determining the target K-space dataset corresponding to the first K-space dataset by filling, based on the at least one second K-space dataset, the undersampled region of the first K-space dataset includes: for each of the plurality of undersampled sub-regions, determining whether there is at least one initial K-space dataset in the at least one second K-space dataset, the initial K-space dataset including an associated sub-region, a K-space position of the associated sub-region corresponding to a K-space position of the undersampled sub-region, and the associated sub-region being fully sampled; in response to determining that there is at least one initial K-space dataset in the at least one second K-space dataset, determining a reference K-space dataset from the at least one initial K-space dataset; and filling the undersampled sub-region based on the reference K-space dataset.

In some embodiments, determining the reference K-space dataset from the at least one initial K-space dataset includes: determining a phase interval between each of the at least one initial K-space dataset and the first K-space dataset; and determining the reference K-space dataset based on the phase interval.

In some embodiments, determining whether there is at least one initial K-space dataset in the at least one second K-space dataset includes: determining at least one candidate K-space dataset from the at least one second K-space dataset, a phase interval between the at least one candidate K-space dataset and the first K-space dataset being within a preset range; and determining whether there is at least one initial K-space dataset in the at least one candidate K-space dataset.

In some embodiments, filling the undersampled sub-region based on the reference K-space dataset includes: determining a phase interval between the reference K-space dataset and the first K-space dataset; determining a target weight based on the phase interval between the reference K-space dataset and the first K-space dataset; and filling the undersampled sub-region based on the target weight and the associated sub-region of the reference K-space dataset.

In some embodiments, determining the target weight based on the phase interval between the reference K-space dataset and the first K-space dataset includes: determining the target weight based on the phase interval and a weight correlation table, the weight correlation table including a correspondence between the target weight and the phase interval.

In some embodiments, for each of the at least one first K-space dataset, determining the target K-space dataset corresponding to the first K-space dataset by filling, based on the at least one second K-space dataset, the undersampled region of the first K-space dataset includes: determining the target K-space dataset by sharing K-space data of the at least one second K-space dataset with the unsampled region of the first K-space dataset, a K-space position of the shared K-space data of the at least one second K-space dataset corresponding to a K-space position of the undersampled region of the first K-space dataset.

In some embodiments, generating the reconstructed image of the imaging object based on the target K-space dataset includes: obtaining a reconstruction mask, the reconstruction mask characterizing a weight and/or a phase corresponding to the at least one second K-space dataset; and generating the reconstructed image by reconstructing, using the reconstruction mask, the target K-space dataset.

In some embodiments, generating the reconstructed image of the imaging object based on the target K-space dataset includes: obtaining a coil sensitivity map; and generating the reconstructed image based on the target K-space dataset and the coil sensitivity map.

In some embodiments, obtaining the coil sensitivity map includes: determining intermediate scan data by performing weighted averaging on the plurality of K-space datasets and/or the target K-space dataset; and generating the coil sensitivity map based on the intermediate scan data.

In some embodiments, the plurality of K-space datasets correspond to at least one slice of the imaging object; and determining the intermediate scan data by performing weighted averaging on the plurality of K-space datasets and/or the target K-space dataset includes: determining, from the plurality of K-space datasets and/or the target K-space dataset, the K-space datasets belonging to the same slice; for each of the at least one slice, determining average scan data for the slice by performing weighted averaging on the K-space datasets of the slice; and generating the intermediate scan data based on the average scan data for the at least one slice.

In some embodiments, generating the reconstructed image of the imaging object based on the target K-space dataset includes: generating an initial image by reconstructing, based on the coil sensitivity map, the target K-space dataset; and generating a target image by inputting the initial image into a preset reconstruction model for iterative reconstruction processing, the reconstructed image including the target image.

In some embodiments, the plurality of K-space datasets are acquired in a preset sampling trajectory; the preset sampling trajectory is complementary and interlaced in a phase direction; for the preset sampling trajectory, an acceleration factor in a central region of K-space is less than a first threshold, and an acceleration factor in a non-central region of K-space is greater than a second threshold; and the first threshold is less than or equal to the second threshold.

In some embodiments, the reconstructed image includes a plurality of target images each of which corresponds to one of the plurality of phases, the method further includes: obtaining an MRI mode; determining a target display image by processing, based on the MRI mode, the plurality of target images; and displaying the target display image.

In some embodiments, in response to determining that the MRI mode includes a static imaging mode, determining the target display image by processing, based on the MRI mode, the plurality of target images includes: selecting one of the plurality of target images corresponding to any phase as the target display image; or selecting one of the plurality of target images that satisfies a preset image quality requirements.

In some embodiments, in response to determining that the MRI mode includes a high-definition imaging mode, determining the target display image by processing, based on the MRI mode, the plurality of target images includes: generating an average scan image by performing averaging on the plurality of target images; and using the average scan image as the target display image.

One or more embodiments of the present disclosure provide an MRI method including: obtaining at least one first K-space dataset from a plurality of K-space datasets corresponding to a plurality of phases of an imaging object. The at least one first K-space dataset is undersampled, and each of the plurality of K-space datasets corresponds to one of the plurality of phases; for each of the at least one first K-space dataset, determining a target K-space dataset by sharing K-space data of at least one of K-space datasets other than the first K-space dataset in the plurality of K-space datasets; obtaining a reconstruction mask, the reconstruction mask characterizing a weight and/or a phase corresponding to the reused K-space data of the at least one second K-space dataset; and generating a reconstructed image of the imaging object based on the reconstruction mask and the target K-space dataset.

In some embodiments, K-space of the first K-space dataset includes a sampled region and an unsampled region; and the determining a target K-space dataset by sharing K-space data of at least one of K-space datasets other than the first K-space dataset in the plurality of K-space datasets includes: sharing the K-space data of the at least one of K-space datasets other than the first K-space dataset in the plurality of K-space datasets with the unsampled region of the first K-space dataset, a K-space position of the shared K-space data of the at least one of K-space datasets other than the first K-space dataset in the plurality of K-space datasets corresponding to a K-space position of the unsampled region of the first K-space dataset.

One or more embodiments of the present disclosure provide a system including: at least one storage device including a set of instructions; and at least one processor in communication with the at least one storage device. When executing the set of instructions, the at least one processor is directed to perform operations including: obtaining at least one first K-space dataset from a plurality of K-space datasets corresponding to a plurality of phases of an imaging object, the at least one first K-space dataset being undersampled, and each of the plurality of K-space datasets corresponding to one of the plurality of phases; for each of the at least one first K-space dataset, determining a target K-space dataset corresponding to the first K-space dataset by filling, based on at least one second K-space dataset, an undersampled region of the first K-space dataset, the at least one second K-space dataset being from the plurality of K-space datasets and corresponding to a different phase from the first K-space dataset; and generating a reconstructed image of the imaging object based on the target K-space dataset.

One or more embodiments of the present disclosure provide a computer-readable storage medium, the storage medium storing computer instructions, and the computer executing an magnetic resonance imaging method when the computer reads the computer instructions in the storage medium.

### BRIEF DESCRIPTION OF THE DRAWINGS

The present disclosure is further illustrated in terms of exemplary embodiments. These exemplary embodiments are described in detail with reference to the drawings. These embodiments are not limiting, and in these embodiments, the same numbering denotes the same structure, wherein:

FIG. 1 is a schematic diagram illustrating an application scenario of a magnetic resonance imaging system according to some embodiments of the present disclosure;

FIG. 2 is a flowchart illustrating an exemplary magnetic resonance imaging method according to some embodiments of the present disclosure;

FIG. 3 is a flowchart illustrating an exemplary process for obtaining intermediate scan data according to some embodiments of the present disclosure;

FIG. 4 is a flowchart illustrating an exemplary magnetic resonance imaging method according to some embodiments of the present disclosure;

FIG. 5 is a flowchart illustrating an exemplary magnetic resonance imaging method according to some other embodiments of the present disclosure;

FIG. 6 is a flowchart illustrating an exemplary magnetic resonance imaging method according to some embodiments of the present disclosure;

FIG. 7 is a flowchart illustrating an exemplary filling process according to some embodiments of the present disclosure;

FIG. 8 is a flowchart illustrating an exemplary filling process according to some other embodiments of the present disclosure;

FIG. 9 is a flowchart illustrating an exemplary process for determining a target K-space dataset according to some embodiments of the present disclosure;

FIG. 10 is a flowchart illustrating an exemplary process for determining an initial K-space dataset according to some embodiments of the present disclosure;

FIG. 11 is a flowchart illustrating a process for filling an undersampled sub-region according to some embodiments of the present disclosure;

FIG. 12 is a flowchart illustrating a process for determining a target weight according to some embodiments of the present disclosure;

FIG. 13 is a flowchart illustrating an exemplary magnetic resonance imaging method according to some other embodiments of the present disclosure;

FIG. 14 is a schematic diagram illustrating an exemplary target K-space dataset according to some embodiments of the present disclosure;

FIG. 15 is a schematic diagram illustrating exemplary interleaved sampling according to some embodiments of the present disclosure;

FIG. 16 is a schematic diagram illustrating exemplary images directly obtained by an inverse Fourier transform according to some embodiments of the present disclosure;

FIG. 17 is a schematic diagram illustrating exemplary images of four phases obtained using a magnetic resonance imaging method according to some embodiments of the present disclosure;

FIG. 18 is a flowchart illustrating an exemplary magnetic resonance imaging method according to some other embodiments of the present disclosure;

FIG. 19 is a flowchart illustrating an exemplary magnetic resonance imaging method according to some embodiments of the present disclosure;

FIG. 20 is a flowchart illustrating an exemplary process for determining a coil sensitivity map according to some embodiments of the present disclosure;

FIG. 21 is a flowchart illustrating an exemplary process for obtaining multi-phase scan images according to some embodiments of the present disclosure;

FIG. 22 is a flowchart illustrating an exemplary process for displaying a magnetic resonance image according to some embodiments of the present disclosure;

FIG. 23 is a flow chart illustrating an exemplary magnetic resonance imaging method according to some embodiments of the present disclosure;

FIG. 24 is a schematic diagram illustrating an exemplary display method according to some embodiments of the present disclosure;

FIG. 25 is a structural diagram illustrating an exemplary magnetic resonance imaging device according to some embodiments of the present disclosure;

FIG. 26 is a structural diagram illustrating an exemplary magnetic resonance imaging device according to some embodiments of the present disclosure;

FIG. 27 is a structural diagram illustrating an exemplary magnetic resonance imaging device according to some embodiments of the present disclosure;

FIG. 28 is a schematic diagram illustrating an exemplary reconstruction method of sensitivity encoding (SENSE) according to some embodiments of the present disclosure;

FIG. 29 is a schematic diagram illustrating an exemplary reconstruction method of generalized autocalibrating partial parallel acquisition (GRAPPA) according to some embodiments of the present disclosure;

FIG. 30 is a schematic diagram illustrating an exemplary magnetic resonance image in a static imaging mode according to some embodiments of the present disclosure;

FIG. 31 is a schematic diagram illustrating an exemplary magnetic resonance image in a dynamic imaging mode according to some embodiments of the present disclosure; and

FIG. 32 is a schematic diagram illustrating an exemplary magnetic resonance image in a high-definition imaging mode according to some embodiments of the present disclosure.

### DETAILED DESCRIPTION

To more clearly illustrate the technical solutions of the embodiments of the present disclosure, the accompanying drawings required to be used in the description of the embodiments are briefly described below. Obviously, the accompanying drawings in the following description are only some examples or embodiments of the present disclosure, and it is possible for those skilled in the art to apply the present disclosure to other similar scenarios in accordance with these drawings without creative labor. Unless obviously obtained from the context or the context illustrates otherwise, the same numeral in the drawings refers to the same structure or operation.

It should be understood that the terms “system,” “device,” “unit,” and/or “module” as used herein is a way to distinguish between different components, elements, parts, sections, or assemblies at different levels. However, the words may be replaced by other expressions if other words accomplish the same purpose.

As shown in the present disclosure and the claims, unless the context clearly suggests an exception, the words “one,” “a,” “an,” and/or “the” do not refer specifically to the singular, but may also include the plural. Generally, the terms “including” and “comprising” suggest only the inclusion of clearly identified operations and elements that do not constitute an exclusive list, and the method or apparatus may also include other operations or elements.

Flowcharts are used in the present disclosure to illustrate operations performed by the system in accordance with embodiments of the present disclosure. It should be appreciated that the preceding or following operations are not necessarily performed in an exact sequence. Instead, operations may be processed in reverse order or simultaneously. Also, it is possible to add other operations to these processes or remove an operation or operations from these processes.

In conventional image reconstruction for magnetic resonance (MR) dynamic imaging, an acceleration factor of approximately 3-5 times can typically be achieved. However, in MR dynamic imaging scenarios with high spatiotemporal resolution, acceleration artifacts can easily occur, resulting in low quality of reconstructed images and limiting the clinical value of MR dynamic imaging. Phased array coils used in MR possess channels that are independent in data acquisition, with each channel acquiring data in an undersampled manner. The spatial information in the coil sensitivity map can serve as a supplement to the undersampled data, and using specific algorithms, it is possible to reconstruct images without aliasing. In some cases, image reconstruction methods for MR dynamic imaging are based on parallel imaging. Exemplary image reconstruction methods based on parallel imaging include sensitivity encoding (SENSE) and generalized autocalibrating partial parallel acquisition (GRAPPA).

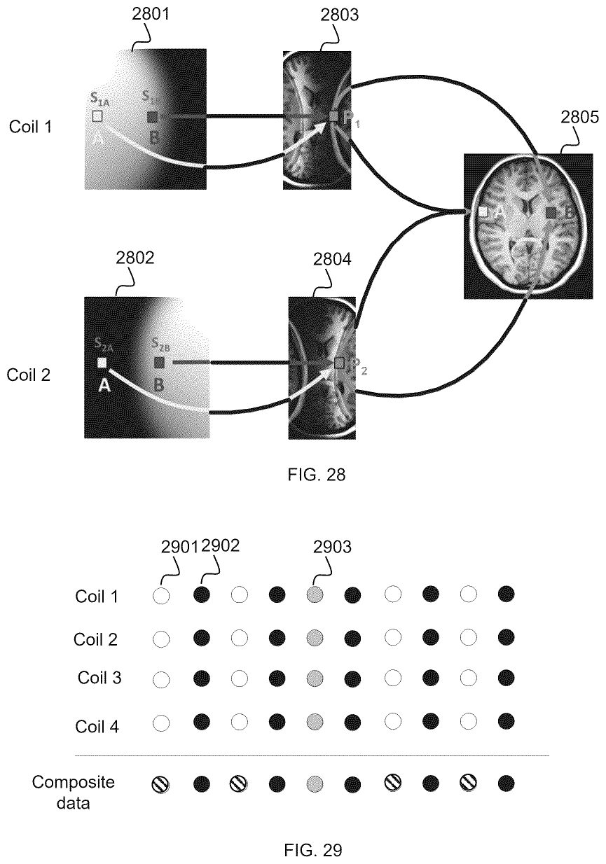

SENSE is an image-domain-based reconstruction technique. The specific process of SENSE includes: performing a Fourier transform on the data from each coil to obtain images including aliasing artifacts; and unaliasing and combining the aliased images to form a complete, aliasing-free image. FIG. 28 is an exemplary schematic diagram of images with aliasing artifacts according to some embodiments of the present disclosure. In FIG. 28, Fourier transform is performed on data from two coils respectively, resulting in images with aliasing artifacts, which are subsequently unaliased and combined into a complete image. In FIG. 28, images 2801 and 2802 are sensitivity maps for coil 1 and coil 2, respectively. In image 2801, coil 1 has a sensitivity of S_{1A} at location A of a region of interest (ROI) in the imaging object, and a sensitivity of S_{1B} at location B of the ROI. in image 2802, coil 2 has a sensitivity of S_{2A} at location A and a sensitivity of S_{2B} at location B of the imaging object. Images 2803 and 2804 are images generated after applying Fourier transform to undersampled K-space data from coil 1 and coil 2, respectively. The images present a partial field of view (FOV) (e.g., ½ FOV as shown in images 2803 and 2804), and are with aliasing artifact (wrap-around (fold-over) artifact). In image 2803, the signal corresponding to pixel P1 is the sum of the contributions of signals that are from points A and B and detected by coil 1. In image 2804, the signal corresponding to pixel P2 is the sum of the contributions of signals that are from points A and B and detected by coil 2. Image 2805 is the complete image generated based on images 2803 and 2804.

GRAPPA is a K-space-based reconstruction technique. GRAPPA requires the provision of auto calibration signal (ACS), which represent a fully sampled region in the low-frequency area of K-space. The ACS is used to iteratively reconstruct the undersampled regions in K-space, yielding images from multiple coils, which are then combined, typically via pixel-by-pixel averaging in the image domain, to obtain the final reconstructed complete image. FIG. 29 is an exemplary schematic diagram of K-space lines according to some embodiments of the present disclosure. In FIG. 29, white circles (e.g., 2901) denote regions in K-space that were not sampled, black circles (e.g., 2902) denote regions in K-space that were sampled, and gray circles (e.g., 2903) denote auto calibration lines of coils 1-4. The composite data is data obtained after reconstructing the unsampled K-space regions using the auto calibration lines. In conventional techniques, the image reconstruction methods tend to exhibit acceleration artifact under high spatiotemporal resolution, resulting in low image quality.

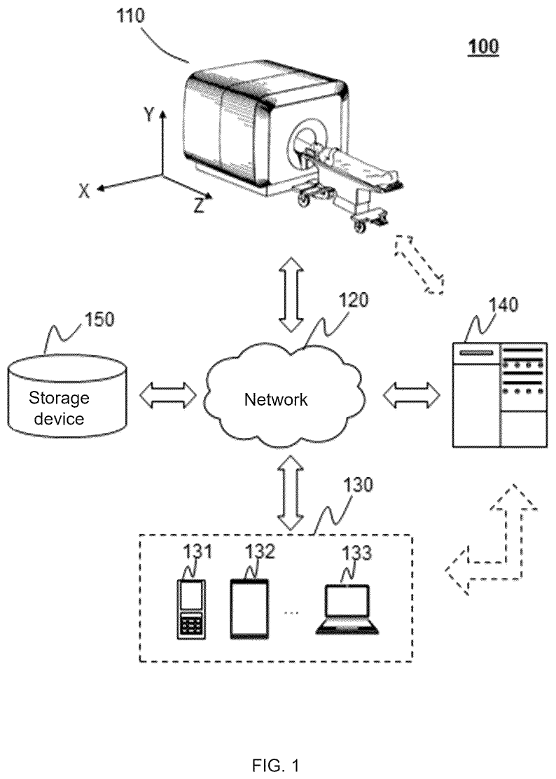

FIG. 1 is a schematic diagram illustrating an application scenario of a magnetic resonance imaging system according to some embodiments of the present disclosure.

As shown in FIG. 1, a magnetic resonance imaging (MRI) system 100 includes an MRI scanner 110, a network 120, a terminal 130, a processing device 140, and a storage device 150. Components of the MRI system 100 may be connected in various manners. Merely by way of example, the MRI scanner 110 is connected to the processing device 140 through the network 120. For another example, the MRI scanner 110 is directly connected to the processing device 140 (as shown by bidirectional arrows in dotted lines connecting the MRI scanner 110 to the processing device 140). For another example, the storage device 150 is connected to the processing device 140 either directly or through the network 120. For another example, the processing device such as terminals 131, 132, 133, etc. is connected directly to the processing device 140 (as shown by the bidirectional arrows in the dotted lines connecting the terminal 130 and the processing device 140) or through the network 120.

The MRI scanner 110 may be configured to scan an object (or a part of an object) to obtain scan data, such as an MRI signal (also referred to as an MR signal) associated with the object. For example, the MRI scanner 110 may obtain a plurality of MRI signals by applying an MRI pulse sequence to the object. In the present disclosure, “object” and “subject” may be used interchangeably. Just as an example, an object may include a patient, an artificial object, etc. Merely by way of example, the object may include a particular part of a patient, an organ, and/or a tissue. For example, the object may include a head, a brain, a neck, a body, a shoulder, an arm, a chest, a heart, a stomach, a blood vessel, a soft tissue, a knee, a foot, etc., or any combination thereof.

The MRI scanner 110 may include a single modality imaging device (e.g., an MRI device) and/or a multi-modality imaging device. The multi-modality imaging device may include, for example, a computed tomography-magnetic resonance imaging (MRI-CT) device, a positron emission tomography-magnetic resonance imaging (PET-MRI) device, a single photon emission computed tomography-magnetic resonance imaging (SPECT-MRI) device, a digital subtraction angiography-magnetic resonance imaging (DSA-MRI) device, etc.

X-axis, Y-axis and Z-axis shown in FIG. 1 may form an orthogonal coordinate system. The X-axis and the Z-axis shown in FIG. 1 may be horizontal and the Y-axis may be vertical. As shown, a positive X direction along the X-axis may be from a right side to a left side of the MRI scanner 110 as seen from a direction facing a front of the MRI scanner 110; a positive Y direction along the Y-axis shown in FIG. 1 may be from a lower part to an upper part of the MRI scanner 110; and a positive Z direction along the Z-axis shown in FIG. 1 may be a direction of the scanning object moving out of the scanning channel (or referred to as a hole) of the MRI scanner 110.

The network 120 may include any suitable network that facilitates an exchange of information and/or data for the MRI system 100. In some embodiments, one or more components of the MRI system 100 (e.g., the MRI scanner 110, the terminal 130, the processing device 140, or the storage device 150) transmit the information and/or data with one or more other components of the MRI system 100 through the network 120. In some embodiments, the network 120 is a wired network or a wireless network, etc., or any combination thereof.

The terminal 130 includes a mobile device 131, a tablet 132, a laptop 133, etc., or any combination thereof. In some embodiments, the mobile device 131 includes a smart home device, a wearable device, a smart mobile device, a virtual reality device, an augmented reality device, etc., or any combination thereof. In some embodiments, the terminal 130 remotely operates the MRI scanner 110 and/or the processing device 140. In some embodiments, the terminal 130 operates the MRI scanner 110 and/or the processing device 140 through the wireless connection. In some embodiments, the terminal 130 receives the data and/or information input by a user, and sends the received data and/or information to the MRI scanner 110 or the processing device 140. In some embodiments, the terminal 130 receives data and/or information from the processing device 140. In some embodiments, the terminal 130 is a part of the processing device 140. In some embodiments, the terminal 130 is omitted.

The processing device 140 processes the data and/or information obtained from the MRI scanner 110, the terminal 130, and/or the storage device 150. For example, the processing device 140 obtains at least one first K-space dataset from a plurality of K-space datasets corresponding to a plurality of phases of an imaging object; for each of the at least one first K-space dataset, determines a target K-space dataset corresponding to the first K-space dataset by filling, based on at least one second K-space dataset, an undersampled region of the first K-space dataset; and generates a reconstructed image of the imaging object based on the target K-space dataset. In some embodiments, the processing device 140 is a single server or a server group. The server group may be centralized or distributed. In some embodiments, the processing device 140 is local or remote.

The storage device 150 stores data and/or instructions. In some embodiments, the storage device 150 stores data obtained from the MRI scanner 110, the terminal 130, and/or the processing device 140. For example, the storage device 150 stores MRI images. In some embodiments, the storage device 150 stores the data and/or instructions that the processing device 140 performs or uses to perform the exemplary methods described in the present disclosure. In some embodiments, the storage device 150 is connected to the network 120 to communicate with one or more components of the MRI system 100 (e.g., the MRI scanner 110, the processing device 140, the terminal 130, etc.). One or more of the components of the MRI system 100 accesses the data or instructions stored in the storage device 150 through the network 120. In some embodiments, the storage device 150 is directly connected to or in communication with one or more components of the MRI system 100 (e.g., the MRI scanner 110, the processing device 140, the terminal 130, etc.). In some embodiments, the storage device 150 is a part of the processing device 140.

It should be noted that the application scenario 100 is disposed for illustrative purposes only and is not intended to limit the scope of the present disclosure. For those skilled in the art, a variety of modifications or variations are made in accordance with the description of the present disclosure. For example, the application scenario 100 also includes an input device and/or an output device. For another example, the application scenario 100 implements similar or different functionality on other devices. However, these changes and modifications do not depart from the scope of the present disclosure.

In some embodiments, the system 100 may include an imaging system. The imaging system may include a single modality imaging system (e.g., an MRI system) and/or a multi-modality imaging system. The multi-modality imaging system may include, for example, a computed tomography-magnetic resonance imaging (MRI-CT) system, a positron emission tomography-magnetic resonance imaging (PET-MRI) system, a single photon emission computed tomography-magnetic resonance imaging (SPECT-MRI) system, a digital subtraction angiography-magnetic resonance imaging (DSA-MRI) system, etc. In some embodiments, the system 100 may include a treatment system. The treatment system may include a treatment plan system (TPS), image-guide radiotherapy (IGRT), etc. The image-guide radiotherapy (IGRT) may include a treatment device and an imaging device. The treatment device may include a linear accelerator, a cyclotron, a synchrotron, etc., configured to perform a radio therapy on a subject. The treatment device may include an accelerator of species of particles including, for example, photons, electrons, protons, or heavy ions. The imaging device may include an MRI scanner (e.g., the MRI scanner 110), an electronic portal imaging device (EPID), etc.

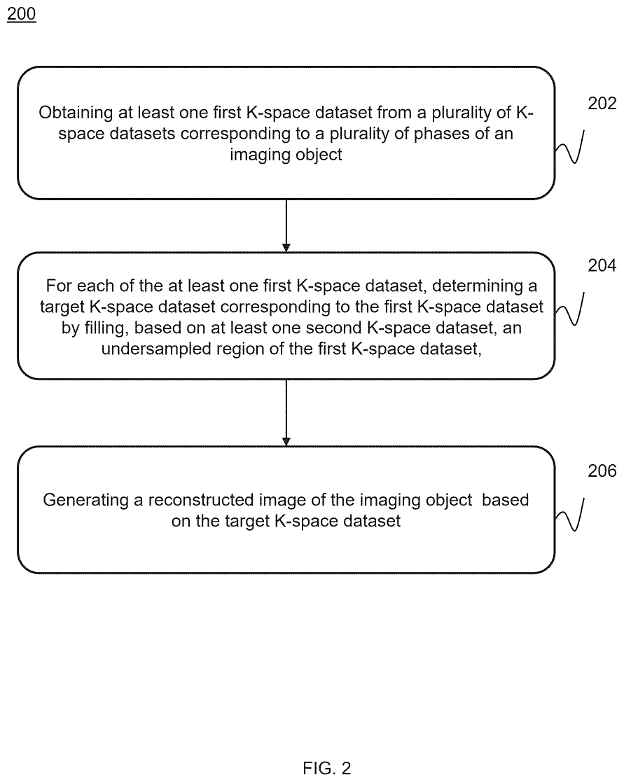

FIG. 2 is a flowchart illustrating an exemplary magnetic resonance imaging method according to some embodiments of the present disclosure. As shown in FIG. 2, a process 200 includes the following operations. In some embodiments, the process 200 is performed by an MRI system (e.g., the processing device 140).

In operation 202, the processing device obtains at least one first K-space dataset from a plurality of K-space datasets corresponding to a plurality of phases of an imaging object. Each of the plurality of K-space datasets corresponds to one of the plurality of phases.

The imaging object refers to an object of a magnetic resonance scan, which includes a patient, a man-made object, etc. For example, the imaging object includes a specific part, an organ, and/or a tissue of the patient. For another example, the imaging object includes a head, a brain, a neck, a body, a shoulder, an arm, a chest, a heart, a stomach, a blood vessel, a soft tissue, a knee, a foot, etc., or any combination thereof.

In some embodiments, an entire data acquisition process (e.g., from applying a scan sequence to the imaging object to finishing the acquisition of the plurality of K-space datasets) is divided into a plurality of time periods, each of which is referred to as a phase. The plurality of phases of the imaging object are determined by monitoring a physiological motion of the imaging object. For example, a respiratory cycle can be divided into six stages: early exhalation, mid-exhalation, late exhalation, early inhalation, mid-inhalation, and late inhalation, each of which is referred to as a respiratory phase. If the data acquisition process includes two respiratory cycles, the data acquisition process may include 12 respiratory phases. The monitoring of the physiological motion of the imaging object may be performed using a camera, a sensor, etc. Alternatively, the entire data acquisition process may be artificially divided into a plurality of phases without referring to the physiological motion of the imaging object. For example, if the time period of the entire data acquisition process is 30 seconds, and every 2 seconds is set as a phase, the entire data acquisition process is divided into 15 phases.

A K-space dataset corresponding to a phase of the imaging object refers to K-space data obtained by the processing device by filling K-space (e.g., two-dimensional (2D) K-space or three-dimensional (3D) K-space) with magnetic resonance signals of the imaging object received during the phase. The magnetic resonance signals may be received using the MRI scanner 110 (e.g., receiving coils) in FIG. 1. The processing device fills the magnetic resonance signals into K-space according to a preset filling manner to form the K-space dataset. The preset filling manner may be a Cartesian filling manner or a non-Cartesian filling manner (e.g., a spiral filling manner, a radial filling manner, etc.).

During a phase, after magnetic resonance signals are generated, the magnetic resonance signals are filled into K-space to obtain the K-space dataset corresponding to the phase. At least one K-space dataset of the plurality of K-space datasets may be obtained by undersampling (e.g., high sparse sampling) K-space.

A first K-space dataset refers to an undersampled K-space dataset selected from the plurality of K-space datasets.

For each K-space dataset, the processing device determines whether an undersampled region exists in the K-space dataset. The undersampled region of a K-space dataset refers to a region in K-space that is unsampled during acquiring the K-space dataset. The processing device determines the K-space dataset having an undersampled region as a first K-space dataset. In some embodiments, the first K-space dataset is also referred to as the K-space data of the phase to be processed.

If a K-space dataset is fully sampled, it may be understood that the K-space dataset is obtained by sampling all necessary data points in K-space, indicating that for the whole K-space (including the low and high frequency regions), a distribution density of the sampling points should satisfy or be greater than that of Nyquist criterion. The full sampling ensures the collection of sufficient K-space data so that MR images can be reconstructed without distortion through the Fourier transform, preventing artifacts such as aliasing. If a K-space dataset is undersampled, it means that a count of sampling points in the K-space dataset is less than a minimum requirement of a count of sampling points of full sampling, i.e., only a part of data points in K-space are sampled. For example, certain phase encoding lines are not sample, or only a part of data points on a phase encoding line is sampled. The undersampling results in a reduced spatial resolution during imaging and artifacts in the reconstructed image.

In some embodiments, the plurality of K-space datasets are acquired through a preset sampling trajectory. For the preset sampling trajectory, regarding each K-space dataset, an acceleration factor in a central region of K-space is less than a first threshold, while an acceleration factor in a non-central region of K-space is greater than a second threshold, and the first threshold is less than or equal to the second threshold. That is, for each K-space dataset, a sampling density of the central region of K-space is greater than a sampling density of the non-central region of K-space. The central region of K-space is a region including low spatial frequency information, e.g., a region within a certain range from the K-space center (e.g., the K-space center of 2D K-space is kx=ky=0; the K-space center of 3D K-space is kx=ky=kz=0; kx relates to the frequency encoding direction, ky relates to the phase encoding direction, and kz relates to the slice selection direction). The range may be determined by a rectangle, a circle or other relevant basis.

The preset sampling trajectories are complementary and interleaved in a phase direction, referring to that the sampling trajectories corresponding to different phases cover different regions in K-space. For example, for a K-space dataset, an undersampled region in the K-space dataset corresponds to a position L in K-space, and the position L in at least one other K-space dataset is fully sampled. Taking the Cartesian sampling manner as an example, it is assumed that K-space includes 15 phase encoding lines 1-15, and phase encoding lines 7-9 are located in the central region of K-space. In phase 1, phase encoding lines 1, 4, 7-9, 12, and 15 are fully sampled (the rest phase encoding lines are not sampled) to obtain K-space dataset 1, in phase 2, phase encoding lines 2, 5, 7-9, 11, and 14 are fully sampled (the rest phase encoding lines are not sampled) to obtain K-space dataset 2, and in phase 3, phase encoding lines 3, 6, 7-9, 10, and 13 are fully sampled (the rest phase encoding lines are not sampled) to obtain K-space dataset 3. The sampling trajectories of the K-space datasets 1-3 are complementary and interleaved in the phase direction. For example, as shown in FIG. 15, which illustrates the sampling trajectories of eight K-space datasets corresponding to phases 1-8, respectively, the white regions refer to the sampled regions, and the black regions refer to the unsampled regions. As shown in FIG. 15, for each phase, a sampling density in the central region of K-space is greater than a sampling density in the non-central regions of K-space, and the sampling trajectories of the 8 K-space datasets are complementary and interleaved in the phase direction.

The preset sample trajectory refers to a preset path or way to sample K-space. The preset sampling trajectory indicates how to select the sampling points in K-space, and the preset sampling trajectory affects an imaging quality, speed, and accuracy. For example, in an MRI scan, common preset sampling trajectories include Cartesian or non-Cartesian sampling trajectory (e.g., a spiral sampling trajectory, a radial sampling trajectory, etc.), and the preset sampling trajectory determines how to sample or fill data points in K-space.

The acceleration factor refers to a ratio of a count of sampling points in full sampling to a count of actual sampling points. For example, if the count of sampling points required for full sampling is 100 and the count of actual sampling points is 50, the acceleration factor is 2.

The first threshold refers to a numerical limit that defines the acceleration factor in the central region of K-space, and a lower acceleration factor is required for the central region of K-space to ensure that the low-frequency information of the image is not lost.

The second threshold refers to a numerical limit that defines the acceleration factor in the non-central region of K-space that allows a higher acceleration factor.

In operation 204, for each of the at least one first K-space dataset, the processing device determines a target K-space dataset corresponding to the first K-space dataset by filling, based on at least one second K-space dataset, an undersampled region of the first K-space dataset. For example, for each of the at least one first K-space dataset, the processing device determines a target K-space dataset corresponding to the first K-space dataset by filling, based on K-space datasets other than the first K-space dataset in the plurality of K-space datasets, an undersampled region of the first K-space dataset.

The following is described by taking determining the target K-space dataset corresponding to one first K-space dataset as an example. For two or more first K-space datasets, similar operations are performed for each first K-space dataset to determine the corresponding target K-space dataset.

The second K-space dataset refers to a K-space dataset in the plurality of K-space datasets that corresponds to a different phase from the first K-space dataset.

The second K-space dataset and the first K-space dataset correspond a similar region of the imaging object, and different sampling time. The second K-space data may be undersampled or fully sampled.

In some embodiments, the plurality of K-space datasets may correspond to at least one slice of the imaging object. If the plurality of K-space datasets correspond to the same slice of the imaging object, the at least one second K-space data refers to at least one K-space dataset except the first K-space dataset among the plurality of K-space datasets. For example, for five K-space datasets 1-5 corresponding to the same slice and five phases, K-space datasets 1-2 are undersampled, and are determined to be the first K-space datasets 1-2. For the first K-space dataset 1, the K-space datasets 2-4 are the second K-space datasets. For the first K-space dataset 2, the K-space datasets 1 and 3-4 are the second K-space datasets. If the plurality of K-space datasets correspond to two or more slices of the imaging object, the at least one second K-space data refers to at least one K-space dataset that corresponds to the same slice as the first K-space dataset, but different phases from the first K-space dataset among the plurality of K-space datasets. For example, for K-space datasets 1-6, K-space datasets 1-3 correspond to slice 1 and phases 1-3, and K-space datasets 4-6 correspond to slice 2 and phases 1-3. K-space dataset 1 is undersampled and is determined as first K-space dataset 1, and K-space dataset 4 is undersampled and is determined as first K-space dataset 2. For the first K-space dataset 1, the K-space datasets 2-3 are the second K-space datasets. For the first K-space dataset 2, the K-space datasets 5-6 are the second K-space datasets.

The undersampled region of the first K-space dataset refers to a region of K-space that is not sampled when the first K-space dataset is acquired, as compared to full sampling.

The processing device may estimate missing K-space data in the undersampled region of the first K-space dataset based on the at least one second K-space dataset to restore an integrity of the first K-space dataset.

The target K-space dataset refers to a K-space dataset obtained by filling the undersampled region in the first K-space dataset. The target K-space dataset may be used for subsequent image reconstruction.

In some embodiments, information in the at least one second K-space dataset is used to supplement the undersampled region of the first K-space dataset by analyzing a data structure of the at least one second K-space dataset.

After determining the first K-space dataset, the processing device fills the undersampled region in the first K-space dataset according to the at least one second K-space dataset to obtain the target K-space dataset.

When the undersampled region in the first K-space dataset includes a plurality of undersampled sub-regions, each of the undersampled sub-regions may be filled based on the at least one second K-space dataset.

For example, for full sampling, phase encoding lines 1-6 in K-space need to be fully sampled, and data points 1-10 in each phase encoding line need to be sampled. When obtaining the first K-space dataset, the phase encoding lines 1, 3, and 5 are sampled and the phase encoding lines 2, 4, and 6 are not sampled. Data points 1, 3, 5, 7, and 9 on the phase encoding line 1 are sampled, and data points 2, 4, 6, 8, and 10 on the phase encoding line 1 are not sampled. Data points 1-10 on the phase encoding lines 3 and 5 are sampled, respectively. A combination of the regions corresponding to the phase encoding lines 2, 4, and 6 and the data points 2, 4, 6, 8, and 10 on the phase encoding line 1 is referred to as the undersampled region of the first K-space dataset. The unsampled data points on the phase encoding lines 1, 2, 4, and 6 are each an undersampled sub-region (e.g., 35 undersampled sub-regions), or the phase encoding line 2 is undersampled sub-region 1, the phase encoding line 4 is undersampled sub-region 2, the phase encoding line 6 is undersampled sub-region 3, and the data points 2, 4, 6, 8, and 10 on the phase encoding line 1 are undersampled sub-region 4.

The following takes the filling of one undersampled sub-region as an example. For a plurality of undersampled sub-regions, similar operations may be performed to fill each undersampled sub-region. A plurality of undersampled sub-regions may be filled one by one, or the filling operations of at least two undersampled sub-regions may be performed in parallel (e.g., at least a portion of the filling operations may be performed at the same time). After filling each of the undersampled sub-regions, the target K-space dataset corresponding to the first K-space dataset is obtained.

In some embodiments, the undersampled region of the first K-space dataset includes a plurality of undersampled sub-regions. Determining the target K-space dataset corresponding to the first K-space dataset by filling, based on the at least one second K-space dataset, the undersampled region of the first K-space dataset includes: for each of the plurality of undersampled sub-regions, determining whether there is at least one initial K-space dataset in the at least one second K-space dataset, the initial K-space dataset including an associated sub-region, a K-space position of the associated sub-region corresponding to a K-space position of the undersampled sub-region, and the associated sub-region being fully sampled; in response to determining that there is at least one initial K-space dataset in the at least one second K-space dataset, determining a reference K-space dataset from the at least one initial K-space dataset; and filling the undersampled sub-region based on the reference K-space dataset.

The K-space position of the associated sub-region corresponds to the K-space position of the undersampled sub-region. When the second K-space dataset is acquired, the associated sub-region is fully sampled. For example, for full sampling, the phase encoding lines 1-6 in K-space need to be fully sampled, and data points 1-10 need to be sampled for each phase encoding line. When acquiring the first K-space dataset, the phase encoding lines 1, 3, and 5 are sampled, and the phase encoding lines 2, 4, and 6 are not sampled. The data points 1, 3, 5, 7, and 9 on the phase encoding line 1 are sampled, and the data points 2, 4, 6, 8, and 10 on the phase encoding line 1 are not sampled. The data points 1-10 on the phase encoding lines 3 and 5 are sampled, respectively. A combination of the regions corresponding to the phase encoding lines 2, 4, and 6, and the data points 2, 4, 6, 8, and 10 on the phase encoding line 1 is referred to as the undersampled region of the first K-space dataset. The phase encoding line 2 is undersampled sub-region 1, the phase encoding line 4 is undersampled sub-region 2, the phase encoding line 6 is undersampled sub-region 3, and the data points 2, 4, 6, 8, and 10 on the phase encoding line 1 are undersampled sub-region 4. In a second K-space dataset 1, the phase encoding line 2 is fully sampled (the data points 1-10 on the phase encoding line 2 are sampled), and the phase encoding line 2 corresponding to the second K-space dataset 1 is the associated sub-region corresponding to the undersampled sub-region 1. In a second K-space dataset 2, the phase encoding line 1 is fully sampled (the data points 1-10 on the phase encoding line 1 are sampled), and the data points 2, 4, 6, 8, and 10 on the phase encoding line 1 corresponding to the second K-space dataset 2 are the associated sub-region of the undersampled sub-region 4. In a second K-space dataset 3, the data points 2, 4, 6, 8, and 10 on the phase encoding line 1 are sampled, and data points 1, 3, 5, 7, 9 on the phase encoding line 1 are not sampled. The data points 2, 4, 6, 8, and 10 on the phase encoding line 1 corresponding to the second K-space dataset 3 are associated sub-region of the undersampled sub-region 4.

The initial K-space dataset refers to a second K-space dataset that includes the associated sub-region. For example, in the above example, for the undersampled sub-region 1, the second K-space dataset 1 is used as the corresponding initial K-space dataset; and for the undersampled sub-region 4, the second K-space datasets 2 and 3 are used as the corresponding initial K-space datasets.

In some embodiments, the processing device determines whether at least one initial K-space dataset exists in the at least one second K-space dataset by: determining at least one candidate K-space dataset from the at least one second K-space dataset, a phase interval between the at least one candidate K-space dataset and the first K-space dataset being within a preset range; and determining whether there is at least one initial K-space dataset in the at least one candidate K-space dataset.

The candidate K-space dataset is a K-space dataset selected from the at least one second K-space dataset. The candidate K-space dataset has a certain phase relationship with the first K-space dataset, e.g., within a preset phase range with regard to the phase of the first K-space dataset. The at least one candidate dataset may be used as a candidate source for filling the undersampled region of the first K-space dataset.

In some embodiments, a phase interval between two phases indicates a positional relationship between the two phases in time. For example, the entire data acquisition process is divided into six phases, chronologically ordered as phases 1-6. The interval between phases 1 and 2 is 1, the interval between phases 1 and 3 is 2, the interval between phases 1 and 4 is 3, and so on. For example, assuming that the K-space dataset corresponding to the phase 2 is the first K-space dataset, the K-space dataset corresponding to the phases 1 and 3-6 is the second K-space dataset, and the preset phase range is less than 3, then the K-space datasets corresponding to the phase 1, the phase 3, and the phase 4 are determined as the candidate K-space datasets.

In some embodiments, if a phase corresponds to a stage of a physiological motion, and if two phases correspond to different cycles of the physiological motion but correspond to the same stage of the physiological motion, the two phases are temporally far apart (e.g., one or more physiological motion cycles), but as the two phases correspond to the same physiological motion stage, the K-space datasets corresponding to the two phases are highly correlated. In this situation, the phase interval between the two phases may be an interval between the physiological motion stages corresponding to the two phases. For example, a respiratory cycle can be divided into six stages: early exhalation, mid-exhalation, late exhalation, early inhalation, mid-inhalation, and late inhalation, each of which is referred to as a respiratory phase. If the entire data acquisition process includes two respiratory cycles, by monitoring the respiratory motion of the imaging object, the entire data acquisition process is divided into 12 phases. The interval between the early inhalation and mid-inhalation is 1, the interval between the early inhalation and late inhalation is 2, the interval between the early inhalation and early exhalation is 3, and so on. The interval between the same respiratory stages corresponding to different respiratory cycles is 0. For an example, phases 1-12 correspond to 6 respiratory stages of a first respiratory cycle and a second respiratory cycle, respectively. Assuming that the K-space dataset corresponding to the phase 2 (corresponding to the mid-inhalation of the first respiratory cycle) is the first K-space dataset, and that the preset phase range is less than 2, then the K-space datasets corresponding to the phase 1 (corresponding to the early inhalation of the first respiratory cycle), the phase 3 (corresponding to the end inhalation of the first respiratory cycle), the phase 7 (corresponding to the early inhalation of the second respiratory cycle), the phase 8 (corresponding to the mid-inhalation of the second respiratory cycle), the phase 9 (corresponding to the end inhalation of the second respiratory cycle) are identified as the candidate K-space datasets.

The preset phase range may be set by the user and stored in the processing device according to an actual application scenario. For example, settings are made based on a motion state of the imaging object. Assuming that the motion state of the imaging object is slow or almost still, considering that an information difference between the phases in a relative static state is smaller, the preset phase range may be set greater (e.g., less than or equal to 5). Assuming that the motion state of the imaging object changes greatly, the preset phase range may be set to be smaller (e.g., less than or equal to 1) to prevent mismatches between the first K-space dataset and the second K-space dataset.

The processing device determines at least one candidate K-space data from the at least one second K-space dataset based on the preset phase range, that is, the second K-space dataset(s) within the preset phase range of the first K-space dataset is determined to be the at least one candidate K-space dataset.

After determining the at least one candidate K-space dataset from the at least one second K-space dataset, the processing device may analyze the at least one candidate K-space dataset to determine whether at least one initial K-space dataset exists in the at least one candidate K-space dataset. For example, the processing device checks whether there is K-space data matching the first K-space dataset in the at least one candidate K-space dataset. The matching may be determined based on conditions such as a K-space position. If a candidate K-space dataset corresponds to a missing part of the first K-space dataset, it may be considered that the candidate K-space dataset is an initial K-space dataset.

In this embodiment, the at least one candidate K-space dataset is determined from the at least one second K-space dataset by setting the preset phase range; and whether at least one initial K-space dataset exists in the at least one candidate K-space data is determined. That is, the K-space datasets that are more related to the first K-space dataset (e.g., temporally closer to the first K-space dataset and/or the physiological motion stages are more related to the first K-space dataset) are first selected from the at least one second K-space dataset, and whether at least one initial K-space dataset exists is then determined from the selected K-space datasets. In this way, the initial K-space dataset may be determined more quickly and more accurately, and at the same time, the MRI method provided by the present disclosure can be applicable to the magnetic resonance image reconstruction of different motion states, which improves an applicability and a reliability of the MRI method.

In some embodiments, the preset phase range is related to a scanning scenario of the imaging object. The scanning scenario includes a body part of the imaging object that is currently being scanned, and a current state of the imaging object (e.g., awake, unconscious, etc.). In some embodiments, the preset phase ranges corresponding to different scanning scenarios are stored in a preset table, which is obtained by empirically construction.

In some embodiments, the preset phase range is further related to a motion characteristic of the imaging object. The motion characteristic refers to a sequence including motion displacements of the scanned part of the imaging object at each (preset) moment/each (preset) small time interval over a period of time. The processing device may construct vectors based on the scanning scenarios and the motion characteristics, which are then matched in the preset table/vector dataset. The preset phase ranges corresponding to different scanning scenarios and motion characteristics are stored in a preset table/vector database, and the preset table may be obtained by empirically construction. The processing device may also obtain a basic range by matching in the preset table based on the scanning scenarios, and according to the motion characteristics, the processing device may expand or contract the aforementioned basic range, and thus determine the preset phase range.

In some embodiments, the operation of determining the at least one candidate K-space dataset is omitted, i.e., whether there is at least one initial K-space dataset is directly determined in the at least one second K-space dataset.

The reference K-space dataset refers to a K-space dataset that is used as a baseline or reference for filling the first K-space dataset, which is used as a comparison or supplement to the first K-space dataset.

In some embodiments, if there is only one initial K-space data, the initial K-space dataset is identified as the reference K-space dataset. In some embodiments, if there is more than one initial K-space dataset, the reference K-space dataset is determined by: determining a phase interval between each of the at least one initial K-space dataset and the first K-space dataset; and determining the reference K-space dataset based on the phase interval. For example, the initial K-space dataset with the smallest phase interval from the first K-space dataset is selected as the reference K-space dataset. For example, if there are initial K-space datasets 1-3 with phase intervals of 1, 2, and 2 from the first K-space dataset, the initial K-space dataset 1 is determined as the reference K-space dataset. For another example, there are initial K-space datasets 1-3, with phase intervals of 1, 1, and 2 from the first K-space dataset, then the initial K-space datasets 1 and 2 are determined as the reference K-space datasets.

The undersampled region in the first K-space dataset includes a plurality of undersampled sub-regions, and for each of the undersampled sub-regions, the processing device may determine a reference K-space dataset from the at least one second K-space dataset. The reference K-space dataset refers to the second K-space dataset configured to fill the undersampled sub-region. The reference K-space dataset corresponding to each undersampled sub-region may be the same or different, i.e., a single reference K-space dataset is used to fill a single undersampled sub-region, or a plurality of undersampled sub-regions.

After obtaining the reference K-space dataset, the processing device may fill the corresponding undersampled sub-region based on the reference K-space dataset to obtain the target K-space data.

In some embodiments, the filling the undersampled sub-region according to the reference K-space dataset includes: identifying, in the reference K-space dataset, K-space data sampled at a K-space position corresponding to the undersampled sub-region, and filling the undersampled sub-region with the K-space data.

In this embodiment, for each undersampled sub-region in the first K-space dataset, a corresponding reference K-space dataset is determined, the undersampled sub-region is filled according to the corresponding reference K-space dataset, and the target K-space dataset is obtained. In this way, all the undersampled sub-regions in the first K-space dataset are filled, so that the quality of the obtained target K-space dataset is improved, and thus the quality of the reconstructed magnetic resonance image is improved.

In some embodiments, the processing device fills the undersampled sub-region based on the reference K-space dataset by: determining a target weight corresponding to the reference K-space dataset based on a phase interval between the reference K-space dataset and the first K-space dataset; and filling the undersampled sub-region based on the target weight and the associated sub-region of the reference K-space dataset.

The target weight refers to a contribution of the reference K-space dataset for filling the undersampled sub-region. In some embodiments, a value of the target weight is determined based on the phase interval, e.g., if the phase interval is smaller (i.e., there is a higher degree of similarity between the two corresponding K-space datasets), the target weight is greater; conversely, if the phase interval is larger, the target weight is smaller. A purpose of setting the target weight is to optimize the quality and accuracy of K-space data used to fill the undersampled sub-region. In some embodiments, the relationship between the target weight and the phase interval is expressed by a formula wₚ=λ·e^{-kx}, where, wₚ denotes the target weight, λ and k denotes a preset parameter, and x denotes the phase interval.

After determining the reference K-space dataset, the processing device determines the target weight based on the phase interval between the reference K-space dataset and the first K-space dataset. The shorter the phase interval, the greater the target weight.

After determining the target weight, the processing device fills the corresponding undersampled sub-region according to the target weight and the reference K-space dataset, i.e., new K-space data is obtained according to the target weight and the fully sampled K-space data in the reference K-space dataset at the position corresponding to the undersampled sub-region. The new K-space data is filled into the undersampled sub-region to obtain the target K-space dataset.

In some embodiments, the processing device determines a product between the fully-sampled K-space data in the reference K-space dataset at the location corresponding to the undersampled sub-region and the target weight to obtain the new K-space data.

For example, the phase encoding line 1 is not sampled when the first K-space dataset is obtained. The phase encoding line 1 corresponding to the first K-space dataset is an undersampled sub-region. The phase encoding line 1 is fully sampled (the data points 1-10 on the phase encoding line 1 are sampled) in the reference K-space dataset 1. In the reference K-space dataset 1, the K-space data corresponding to the data points 1-10 on the phase encoding line 1 is

$${k}_{1}^{1} , {k}_{2}^{1} , … , {k}_{10}^{1} ;$$

and the target weight corresponding to the reference K-space dataset 1 is w₁. The new K-space data corresponding to the data point 1 on the phase encoding line 1 in the first K-space dataset is

$${k}_{1}^{′} = {k}_{1}^{1} \times {w}_{1} .$$

The new K-space data corresponding to the data point 2 on the phase encoding line 1 in the first K-space dataset is

$${k}_{2}^{′} = {k}_{2}^{1} \times {w}_{1} ,$$

and so on. The new K-space data

$${k}_{1}^{′} , {k}_{2}^{′} , … , {k}_{10}^{′}$$

is filled into the undersampled sub-region of the first K-space dataset to obtain the target K-space dataset corresponding to the first K-space dataset. On the basis of the reference K-space dataset 1, if there is a further reference K-space dataset 2, in the reference K-space dataset 2, the K-space data corresponding to the data points 1-10 on the phase encoding line 1 is

$${k}_{1}^{2} , {k}_{2}^{2} , … , {k}_{10}^{2} ,$$

respectively, and the target weight corresponding to the reference K-space dataset 2 is w₂. The new K-space data corresponding to the data point 1 on the phase encoding line 1 in the first K-space dataset is

$${k}_{1}^{′} = {k}_{1}^{1} \times {w}_{1} + {k}_{1}^{2} \times {w}_{2} ,$$

the new K-space data corresponding to the data point 2 on the phase encoding line 1 in the first K-space dataset is

$$\begin{matrix}{k}_{2}^{′} = {k}_{2}^{1} \times {w}_{1} + \\ {k}_{2}^{2} \times {w}_{2} ,\end{matrix}$$

and so on.

In this embodiment, the target weight is determined based on the phase interval between the reference K-space dataset and the first K-space dataset; and the target K-space data is obtained by filling the corresponding undersampled sub-region based on the target weight and the reference K-space dataset. This improves the accuracy of the determined target K-space data, which in turn improves the reconstructed magnetic resonance image of the imaging object.

In some embodiments, after determining the reference K-space dataset, determining the target weight based on the phase interval includes: determining the target weight based on the phase interval and a weight correlation table, the weight correlation table including a correspondence between the target weight and the phase interval. In some embodiments, the processing device may select the weight correlation table based on the scanning scenario of the imaging object.

The weight correlation table may be preset and stored in the processing device. The weight correlation table includes different weights corresponding to different phase intervals. After determining the phase interval between the reference K-space dataset and the first K-space dataset, the processing device determines a weight corresponding to the phase interval in the weight correlation table based on the phase interval, and determines the weight as the target weight.

In some embodiments, the relationship between the target weight and the phase interval is represented by the formula wₚ=λ·e^{-kx}, wherein wₚ denotes the target weight, λ and k denotes preset parameters, and x denotes the phase interval.

In this embodiment, the target weight is determined directly based on the weight correlation table, so that the determination of the target weight is quick and convenient, which improves the efficiency of determining the target K-space data, and improves the efficiency of reconstructing the magnetic resonance image of the imaging object.

In some embodiments, there are more than one preset and stored weight correlation table, and different weight correlation tables correspond to different scanning scenarios for different imaging objects.

The processing device may select a suitable weight correlation table based on a type of the imaging object and the characteristics of the scanning scenario. Different weight correlation tables may be used for different imaging objects and scanning scenarios, and different scanning scenarios may have different phase difference patterns during sampling and imaging. For example, when performing a heart scan, a weight correlation table designed for heart scans is selected, and when performing a brain scan, a weight correlation table for brain scans is selected. The weight correlation tables corresponding to different scenarios have different target weights corresponding to the same phase interval. For example, the heart scans are more sensitive to temporal changes than the brain scans. Therefore, for the same phase interval, the target weight is smaller in the weight correlation table corresponding to the heart scans.

In some embodiments, the processing device may also select a corresponding weight correlation table based on the scanning scenario and motion characteristics of the imaging object. For example, the selection is made based on a pre-established correspondence between the weight correlation table, the scanning scenario, and the motion characteristics.

The processing device may reuse the K-space data of the at least one second K-space dataset to fill the undersampled region of the first K-space dataset, and determine the target K-space dataset. That is, the processing device may share the K-space data of the at least one second K-space dataset with the undersampled region of the first K-space dataset, so as to fill the undersampled region of the first K-space dataset with the shared K-space data of the at least one second K-space dataset, thereby determining the target K-space dataset. The K-space position of the reused or shared K-space data of the at least one second K-space dataset corresponds to the K-space position of the undersampled region of the first K-space dataset.

For each undersampled sub-region, the processing device may determine, based on the K-space position of the K-space data of the undersampled sub-region in the first K-space dataset, whether there is K-space data in the at least one second K-space dataset sampled at the K-space position corresponding to the undersampled sub-region; and determine, as the reference K-space dataset, at least one second K-space dataset in which K-space data is fully sampled at the corresponding K-space position of the undersampled sub-region. That is, the processing device selects at least one reference K-space dataset from the at least one second K-space dataset, and select the K-space data from the at least one reference K-space dataset to fill the undersampled region in the first K-space dataset.

If the processing device determines that at least one initial K-space dataset exists in the at least one second K-space dataset by analyzing the at least one second K-space dataset, the processing device determines the phase interval between each of the at least one initial K-space dataset and the first K-space dataset, and determines, based on the phase interval and the at least one initial K-space dataset, the reference K-space dataset.

In some embodiments, if there is only one initial K-space data, the initial K-space dataset is identified as the reference K-space dataset. In some embodiments, if there is more than one initial K-space dataset, the reference K-space dataset is determined by: determining a phase interval between each of the at least one initial K-space dataset and the first K-space dataset; and determining the reference K-space dataset based on the phase interval. For example, the initial K-space dataset with the smallest phase interval from the first K-space dataset is selected as the reference K-space dataset.

For an undersampled sub-region in the first K-space dataset, if the processing device analyzes the at least one second K-space dataset and determines that no initial K-space dataset exists in the at least one second K-space dataset, there is no need to fill the undersampled sub-region.

In this embodiment, whether there is at least one initial K-space dataset capable of filling the undersampled sub-region of the first K-space dataset is first determined in the at least one second K-space dataset; in response to determining that there is at least one initial K-space dataset, the reference K-space dataset is determined from the at least one initial K-space dataset based on the phase interval between the at least one initial K-space dataset and the first K-space dataset. This ensures that the reference K-space dataset is able to more accurately fill the undersampled sub-region of the first K-space dataset, thereby improving the quality of the magnetic resonance image of the imaging object.

In some embodiments, for an undersampled sub-region of the first K-space dataset, the processing device may first search in a second K-space dataset with a phase interval of 1 or 0 relative to the first K-space dataset to determine whether the second K-space dataset is fully sampled at the K-space position corresponding to the undersampled sub-region. In response to determining that the second K-space dataset is fully sampled at the K-space position corresponding to the undersampled sub-region, the corresponding K-space data is selected from the second K-space dataset to be reused or shared, with the corresponding target weight, to fill the undersampled subregion of the first K-space dataset. In response to determining that the second K-space dataset is unsampled at the K-space position corresponding to the undersampled sub-region, meaning that the corresponding K-space position in the second K-space dataset is also unsampled, the process continues by iterating through a second K-space dataset with a phase interval of 2 relative to the first K-space dataset, and so on, until all the second K-space datasets have been examined. After the iteration, if all the second K-space datasets are unsampled at the corresponding K-space position, there is no need to fill the undersampled sub-region.

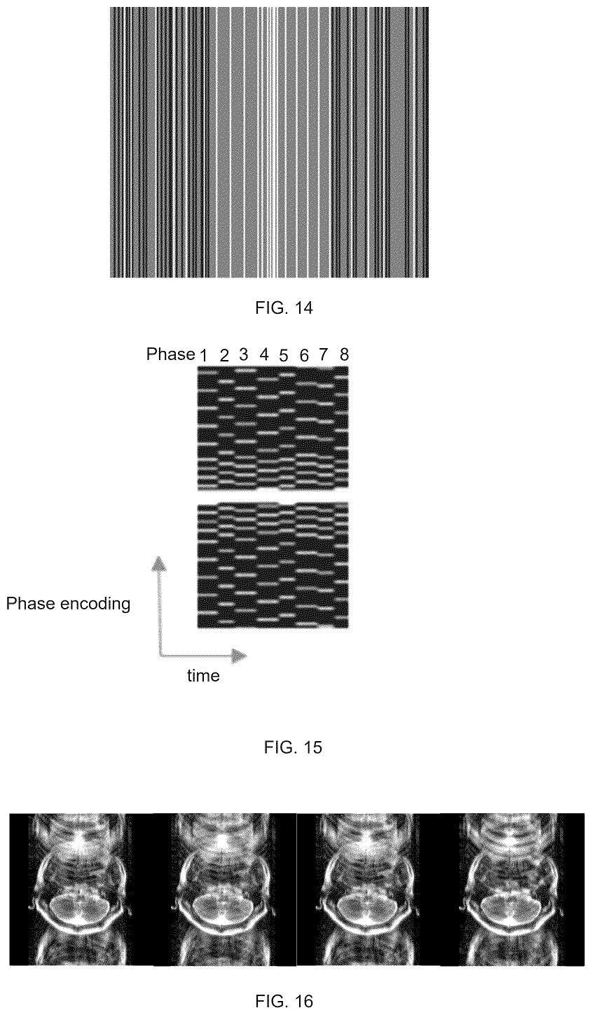

FIG. 14 is a schematic diagram illustrating an exemplary target K-space dataset according to some embodiments of the present disclosure. In FIG. 14, white regions represent actual sampled regions, gray regions represent K-space data obtained by filling undersampled sub-regions according to the method provided by the present disclosure, and black regions represent the undersampled sub-regions which are still unfilled after traversing all the second K-space datasets.

In some embodiments, the plurality of first K-space datasets are filled sequentially (one by one) to obtain the corresponding target K-space datasets, or the filling operation of at least two first K-space datasets are performed in parallel (e.g., at least a portion of the filling operations of the at least two first K-space datasets are performed simultaneously).

In some embodiments, the processing device obtains at least two first K-space datasets from the plurality of K-space datasets of the imaging object. The processing device may arrange the at least two first K-space datasets in a preset sequence; process the at least two first K-space datasets one by one according to the preset sequence, and determine a target K-space dataset corresponding to each first K-space dataset.

When the K-space datasets of the imaging object includes a plurality of first K-space datasets, after determining one first K-space dataset in the K-space datasets of the imaging object, the processing device fills the undersampled region of the first K-space dataset according to at least one second K-space dataset, to obtain the target K-space data corresponding to the first K-space dataset.

After the processing device fills the undersampled region of the first K-space dataset to obtain the target K-space data, the processing device obtains a next first K-space dataset from the K-space datasets and fills the next first K-space dataset to obtain the target K-space dataset corresponding to the next first K-space dataset.

In some embodiments, the processing device sorts the first K-space datasets of the K-space datasets in the preset sequence, and determine which first K-space dataset is the first one to be filled, and which first K-space dataset is the next one to be filled based on the preset sequence.

In this embodiment, in the situation where the K-space datasets include a plurality of first K-space datasets, the undersampled region of each first K-space dataset is filled to obtain the target K-space dataset corresponding to the each first K-space dataset. In this way, each first K-space dataset is processed to improve an accuracy of the target K-space dataset, and thus improving quality of a magnetic resonance image reconstructed from the target K-space dataset.

In operation 206, the processing device generates a reconstructed image of the imaging object based on the target K-space dataset.

The reconstructed image refers to a spatial domain image obtained by reconstructing the target K-space dataset. The reconstructed image is capable of demonstrating a structure and functional characteristics of the imaging object. In some embodiments, for each phase, a target image corresponding to the phase is generated based on the corresponding target K-space dataset. The reconstructed image includes target images corresponding to the plurality of phases.

In some embodiments, the processing device converts the target K-space dataset into the image domain by inverse fast Fourier transform (IFFT) to obtain a reconstructed image of the imaging object. The reconstructed image of the imaging object may also be generated by various image reconstruction algorithms (e.g., a conventional Fourier reconstruction, a parallel imaging reconstruction, a sparse reconstruction, an iterative reconstruction, a reconstruction algorithm based on machine learning, etc.).

After obtaining the target K-space dataset, the target K-space dataset is reconstructed to obtain a magnetic resonance image (the reconstructed image) of the imaging object. This embodiment does not limit the specific manner of reconstructing the target K-space dataset to obtain the magnetic resonance image of the imaging object as long as functions thereof are realized.

In some embodiments, the processing device uses a SENSE manner for reconstructing the target K-space dataset, or uses a GRAPPA manner for reconstructing the target K-space dataset or other auto-calibrated parallel imaging algorithms.

In some embodiments, the processing device reconstructs the target K-space dataset using a trained reconstruction model to obtain the magnetic resonance image of the imaging object.

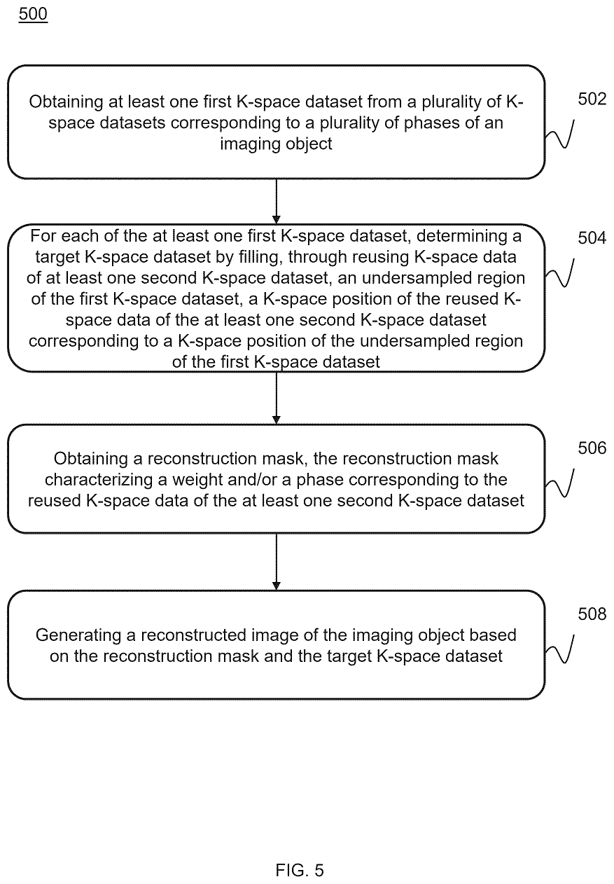

In some embodiments, the processing device generates the reconstructed image of the imaging object by: obtaining a reconstruction mask, the reconstruction mask characterizing a weight and/or a phase corresponding to the at least one second K-space dataset; and generating the reconstructed image by reconstructing, using the reconstruction mask, the target K-space dataset. Specific descriptions may be found in FIG. 5.

In some embodiments, generating a reconstructed image of the imaging object based on the target K-space dataset includes the operations of: obtaining a coil sensitivity map; and generating the reconstructed image based on the target K-space dataset and the coil sensitivity map.

The coil sensitivity map refers to an image obtained by measuring or estimating a signal response strength of each receiving coil in the MRI scanner 110 to different positions in space. The coil sensitivity map reflects spatial distribution characteristics of each receiving coil and its ability to perceive signals at different positions.

In some embodiments, the processing device obtains the coil sensitivity map by obtaining the response strength of each coil to different positions from previous (historical) scan data or through a specific calibration procedure. For example, by calibrating or measuring the imaging area, sensitivity values for each receiving coil at different spatial positions are obtained.

In some embodiments, the processing device may also determine intermediate scan data by performing weighted averaging on the plurality of K-space datasets and/or the target K-space dataset; and generate the coil sensitivity map based on the intermediate scan data. For example, there are 5 K-space datasets 1-5 of the imaging object. K-space datasets 1-4 are the first K-space datasets, and target K-space datasets 1-4 correspond to K-space datasets 1-4, respectively. The processing device may determine intermediate scan data by performing weighted averaging on K-space datasets 1-5, or target K-space datasets 1-4 and K-space dataset 5.

The intermediate scan data refers to an intermediate result obtained by weighted averaging of the K-space datasets and/or the target K-space dataset.

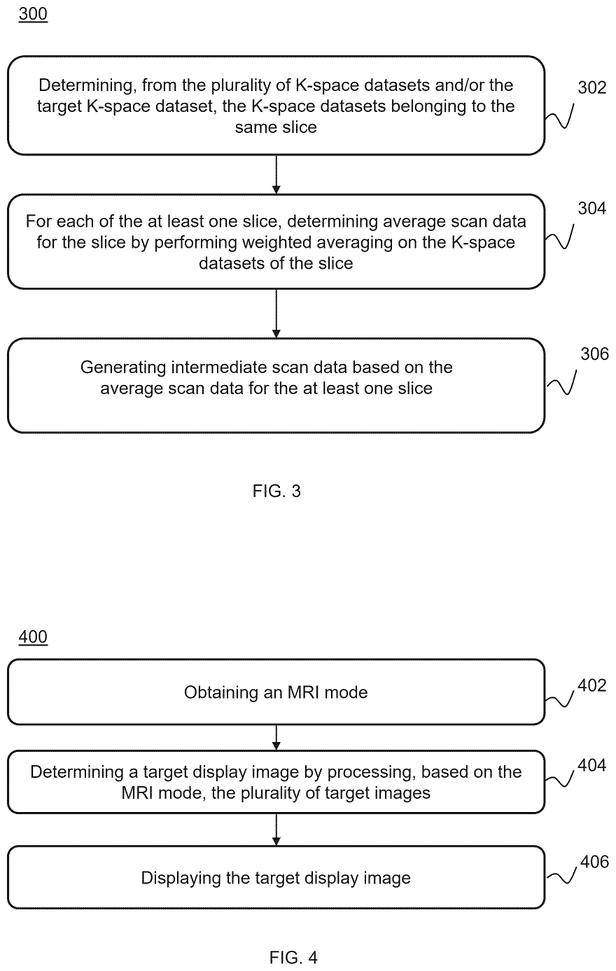

The manner for generating the intermediate scan data based on the K-space datasets and/or the target K-space dataset may be found in FIG. 3.

In some embodiments, the processing device estimates and obtains the sensitivity of each receiving coil by applying a mathematical model or calculation manner using the intermediate scan data. For example, the processing device performs Fourier transform on the intermediate scan data, and estimate the spatial response characteristics of each coil to obtain the coil sensitivity map, such as using a weighting manner, an interpolation manner, or other signal processing techniques.

That is, in a situation where full-sampled intermediate scan data is determined, the processing device determines sensitivity information of each coil based on the fully sampled intermediate scan data, and obtains the coil sensitivity map.

In this embodiment, the processing device first performs data pre-processing on the K-space datasets and/or the target K-space dataset to obtain the intermediate scan data; and then determines the coil sensitivity map based on the fully sampled intermediate scan data. Adopting the method in this embodiment to determine the coil sensitivity map through the pre-processing, not only the efficiency of the data acquisition as well as the accuracy of determining the coil sensitivity map are improved.

In some embodiments, combining the sensitivity of different coils to signals, the processing device uses the target K-space dataset (and/or the K-space datasets) and the coil sensitivity image to finally generate a reconstructed image by converting the K-space data into a spatial-domain image by Fourier inversion.

In this embodiment, the coil sensitivity map is determined based on the K-space datasets and/or the target K-space data set. The coil sensitivity map is used to characterize the sensitivity information of each coil. Further, when the coil sensitivity map is obtained, the image reconstruction may be performed on the K-space datasets and/or the target K-space dataset of the phases based on the coil sensitivity map, to obtain a target image of each phase, i.e., a multi-phase image of the imaging object.

The multi-phase image of the imaging object is the reconstructed image of the imaging object. For example, a preset image reconstruction model is used, and the K-space datasets and/or the target K-space dataset of the phases and the coil sensitivity map of the coils are input into the preset image reconstruction model for processing, and the multi-phase image of the imaging object is obtained.

In some embodiments, for each phase, the target K-space dataset or the K-space dataset is reconstructed based on the coil sensitivity map to generate an initial image corresponding to the phase. The initial image is input into a preset reconstruction model for an iterative reconstruction process to generate a target image. The reconstructed image includes the target image corresponding to the plurality of phases.

For example, the processing device may generate an initial image of a phase by performing, based on the coil sensitively map, reconstruction on a first K-space dataset of the phase, or a target K-space dataset corresponding to the first K-space dataset.

The initial image refers to an initial image reconstruction result based on the coil sensitivity map and the K-space data (the target K-space dataset or the K-space dataset). The initial image may be obtained by performing the image reconstruction (e.g., using the inverse Fourier transform) on a combination of the K-space data (the target K-space dataset or the K-space dataset) and the coil sensitivity map.

In some embodiments, the processing device uses a preset image reconstruction algorithm to perform the image reconstruction on the K-space dataset or the target K-space dataset of each phase based on the coil sensitivity map, so as to obtain the initial image of each phase. The preset image reconstruction algorithm may be any one of the image reconstruction algorithms in the related art, and the embodiments of the present disclosure do not make any specific limitations thereon.

The preset reconstruction model may be a defined mathematical or computational model for processing and optimizing images. The preset reconstruction model may include algorithms and required parameter settings for the image reconstruction, such as an iterative algorithm, a regularization technique, a weighting strategy, etc.

In some embodiments, the preset reconstruction model adopts any one of a deep learning model, a machine learning model, etc. For example, the preset reconstruction model is a deep learning iterative reconstruction model based on a physical model, and the preset reconstruction model includes two parts: a data consistency term and a deep learning network. A purpose of the data consistency term is to ensure that a result of each iteration is consistent with actually acquired data, e.g., argmin∥Ax−b∥2 is solved by a conjugate gradient descent method, where, A denotes an operation operator including a sampling trajectory of an image and the Fourier transform, b denotes K-space data actually acquired, x denotes the K-space data to be solved, argmin denotes a minimization operation, and ∥|∥2 denotes a two-paradigm operation. The deep learning network part may be a 3D convolutional network based on U-Net. Based on the reconstruction model, for each phase, the initial image of the phase and the coil sensitivity map may be used as the input to the preset reconstruction model to perform an iterative reconstruction until an image that satisfies a preset iteration termination condition is obtained, and the image is taken as the target image for the phase.

Exemplarily, the preset iteration termination condition includes, but is not limited to, a preset count of iterations, a preset loss threshold, and a preset image quality requirement, etc.

In some embodiments, when performing multi-phase image reconstruction, the K-space dataset or the target K-space dataset of each phase is first reconstructed according to the coil sensitivity map to obtain the initial image of the phase; then the initial image of the phase is input into the preset reconstruction model for the iterative reconstruction process, to obtain the target image of the phase. In this way, the target image of each phase is reconstructed, and ultimately the multi-phase image is obtained, which improves the efficiency of image reconstruction and quality of the reconstructed images.

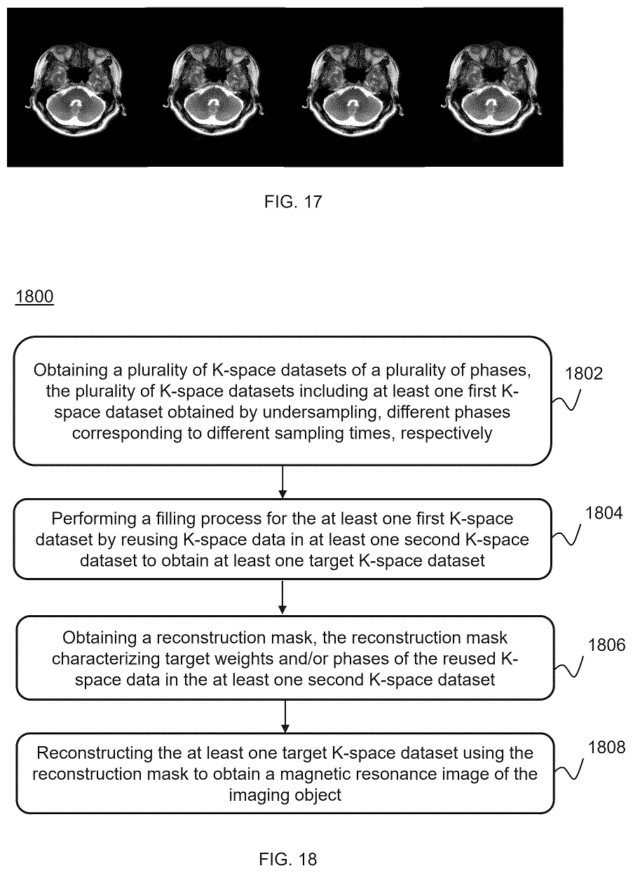

As shown in FIG. 16, taking 4-phase highly accelerated head magnetic resonance dynamic data (the first K-space datasets) as an example, FIG. 16 shows the images obtained by directly performing inverse Fourier transform on the first K-space datasets corresponding to the 4 phases. It can be seen that each image has very serious aliasing artifacts and noise. After the first K-space datasets corresponding to the four phases are filled and reconstructed using the reconstruction manner (e.g., the process 200) proposed in the present disclosure, the resultant images are shown in FIG. 17. It can be seen that the images in FIG. 17 have no aliasing artifacts and noise, and the image quality is higher.

The magnetic resonance imaging method provided in the embodiments of the present disclosure fills the undersampled region in the first K-space dataset using at least one second K-space dataset, that is, sharing the K-space data across different phases to obtain a target K-space dataset, based on which a magnetic resonance image of the imaging object is obtained. Compared with conventional MR dynamic imaging methods, under conditions of high undersampling factors, the MRI method provided herein is capable of sharing temporal and spatial information from different phases to fill the undersampled region in the first K-space dataset, thereby improving the quality of the reconstructed MR images while maintaining high spatiotemporal resolution. Exemplarily, the magnetic resonance imaging method provided herein can achieve MR dynamic imaging reconstruction with an acceleration factor of up to 20 while ensuring high spatiotemporal resolution.

FIG. 3 is a flowchart illustrating an exemplary process for obtaining intermediate scan data according to some embodiments of the present disclosure.

In some embodiments, the plurality of K-space datasets (the plurality of phases) correspond to at least one slice of the imaging object. A slice refers to a section (in 2D imaging) or a volume (in 3D imaging) of the imaging object.

In operation 302, the processing device determines, from the plurality of K-space datasets and/or the target K-space dataset, the K-space datasets belonging to the same slice.

In operation 304, for each of the at least one slice, the processing device determines average scan data for the slice by performing weighted averaging on the K-space datasets of the slice.

The average scan data refers to the scan data obtained by weighted averaging the K-space datasets corresponding to the slice. Weighted averaging is performed on the K-space data corresponding to the same K-space position to obtain the average scan data. A specific way of weighted averaging may be found in the above relevant descriptions, which is not repeated here.

In operation 306, the processing device generates the intermediate scan data based on the average scan data for the at least one slice.

After obtaining the averaged scan data for each slice, the processing device may utilize the averaged scan data to generate the intermediate scan data. For example, the averaged scan data of all the slices are combined to form the intermediate scan data. The averaged scan data corresponding to the same K-space position may be added together to obtain the intermediate scan data.

With the development of medical imaging technology, different imaging manners have emerged to meet different imaging needs. For example, the MRI scan includes static imaging and dynamic imaging according to temporal resolution of imaging. The static imaging requires a longer scan time, and the image obtained from a single scan is an average of a motion state in a scan region of the patient throughout the scan process, which is unable to accurately reflect a real state of the scan region. The dynamic imaging has a high temporal resolution, which reflects the true motion of the scan region. But for the dynamic imaging, the image resolution is generally low, and the detail performance is poor, so the dynamic imaging is only used for an observation of the motion state. That is, the image of static imaging is the average of the motion state during the whole scan process, which is unable to accurately reflect the real state of the scan area; while the dynamic imaging has a high temporal resolution, which reflects the real motion state of the scan region.

An MR dynamic imaging technique includes two kinds of imaging methods. One is a cine MRI technique based on a balanced steady-state free precession (BSSFP) sequence, which has a fast imaging speed and a high temporal resolution, but has a poor image contrast, a low image resolution, and black-banding artifacts. The other is a single-excitation fast spin echo (FSE) sequence, which is able to realize a transverse relaxation time (T2) contrast, but the image resolution is not high, and a too-long echo chain leads to a blurring effect of the image.

It is evident that while dynamic imaging offers high temporal resolution, the image resolution of the dynamic imaging is poor and the image quality of the dynamic imaging is low. Moreover, MR scanning takes a long time. Taking pelvic scanning as an example, involuntary peristalsis in the intestines can easily cause artifacts, which cannot be controlled by the patient. Some technicians administer anticholinergic drugs (such as hyoscine butylbromide tablets) to the patient during scanning to relax the pelvic floor muscles and suppress intestinal peristalsis. However, these drugs have significant side effects that can cause difficulty in urination and lead to a poor patient experience. Alternatively, in some hospitals, technicians ask patients to refrain from drinking water to mitigate motion artifacts caused by intestinal peristalsis, yet inevitably, there remains a certain probability of artifacts.

In addition, traditional MR imaging scans are typically performed using a single imaging method to obtain the corresponding scan images. The limitations inherent in the conventional imaging approaches also determine that the way in which images are displayed is relatively simplistic. Whether it is static or dynamic imaging, the final results are presented sequentially based on the scanning slice dimension.

In view of the above, to address the pain points faced by static and dynamic MR scanning, some embodiments of this disclosure propose a novel whole-body real-time MR imaging technology. This technology can be used for high-definition static imaging as well as for fast dynamic imaging. Both modes can accurately reproduce the actual motion state of the scanned region, providing diagnostic physicians with high-quality and highly accurate objective evidence.

Furthermore, pertaining to the real-time imaging technology provided in the embodiments of this disclosure, a new image browsing and interaction mode, real-time image browsing, is proposed. This image browsing and interaction mode is mainly divided into the following three modes. a. Static mode, where only one phase image is displayed per slice; the number of images is the fewest, and this can serve as the default image browsing mode for real-time imaging. In this mode, the effect is consistent with conventional static imaging, which can meet the needs of most clinical scanning scenarios. b. Multi-phase dynamic browsing mode, in which images are displayed in multiple phases according to the slice dimension, allowing the user to observe the complete scanning process. In this mode, the number of images is the greatest, and it is mainly used in scenarios where the user needs to observe the motion of the scanned region or compare differences between adjacent phases to assist in decision making. c. Averaging mode (also referred to as high-definition mode), where the image shown for each slice is an average over multiple phases of that slice, providing the highest signal-to-noise ratio (SNR), and is generally used when the scanned region is almost stationary and the user wishes to further improve the signal-to-noise ratio of the image.

The MR real-time imaging technology and the image browsing interaction mode provided in the embodiments of this disclosure enable users to quickly and flexibly switch between different image modes according to diagnostic needs, thereby breaking through the limitations of the time dimension in conventional MR imaging.

For example, during imaging, static imaging, dynamic imaging, or averaging imaging modes can be employed for MR imaging.

In other words, the processing device can perform MR imaging based on the imaging mode and the multi-phase scanning data to obtain a target image; on this basis, the processing device can also output and display the target image to facilitate convenient viewing by the user of the target image of the imaging object.

For example, before the MR scan, after the MR scan, or during the MR scan, the user can select an MR imaging mode so that the processing device can generate a target display image corresponding to the user-selected imaging mode based on the multi-phase target images.

For example, if the user does not select an MR imaging mode, the processing device can also generate a target display image corresponding to a default imaging mode based on the multi-phase target images. The default imaging mode may include at least one of static imaging, dynamic imaging, or averaging imaging. The following will be explained in detail with reference to the accompanying drawings.

FIG. 4 is a flowchart illustrating an exemplary magnetic resonance imaging method according to some embodiments of the present disclosure.

In some embodiments, as illustrated in FIG. 2, a reconstructed image includes a plurality of target images, each of which corresponds to one of a plurality of phases.

The plurality of target images may correspond to at least one slice of the imaging object. For example, the reconstructed image includes target images 1-6, wherein target images 1-3 correspond to phases 1-3 and slice 1, and target images 4-6 correspond to phases 1-3 and slice 2.

In operation 402, the processing device obtains an MRI mode.

The MRI mode may include at least one of a static imaging mode, a dynamic imaging mode, and an average imaging mode. The average imaging mode may also be referred to as a high-definition (HD) imaging mode.

Exemplarily, before or after the target images are generated, or during the process for generating the target images, a user selects a required MRI mode so that the processing device obtains the MRI mode selected or entered by the user.

Exemplarily, if the user does not select the required MRI mode, the processing device obtains a default MRI mode.

Exemplarily, after the processing device displays the target images according to the MRI mode selected by the user, or the default MRI mode, if the user wants to modify the MRI mode or to view the target images of another MRI mode, the user may also reselect or modify the MRI mode, so that the processing device display the target images according to the reselected or modified MRI mode.

In operation 404, the processing device determines a target display image by processing, based on the MRI mode, the plurality of target images.

The target display image is an image obtained by processing according to the MRI mode. The processing mode includes image selection, image averaging, etc. In some embodiments, for each slice, the processing device may select one of the target images corresponding to the slice as the target display image corresponding to the slice in the static imaging mode. For example, the reconstructed image includes target images 1-6, wherein target images 1-3 correspond to phases 1-3 and slice 1, and target images 4-6 correspond to phases 1-3 and slice 2. In the static imaging mode, the processing device may select target image 1 as the target display image corresponding to slice 1, and select target image 4 as the target display image corresponding to slice 2.

The following description takes determination of the target display image corresponding to one slice in the static imaging mode as an example.

In some embodiments, when the MRI mode is determined to include the static imaging mode, for a slice, the processing device arbitrarily selects a target image from the target images corresponding to the slice as the target display image corresponding to slice in the static imaging mode; alternatively, according to a preset image quality requirement, a target image satisfying the preset image quality requirement is selected from the target images corresponding to the slice as the target display image corresponding to the slice in the static imaging mode. The target display image corresponding to the slice in the static imaging mode includes one of the target images corresponding to the slice. That is, when determining that the MRI mode includes the static imaging model, for the target images corresponding to a slice, one of the target images corresponding to any phase may be selected as the target display image corresponding to the slice in the static imaging mode.

In some embodiments, the processing device also selects one of the target images that satisfies a preset image quality requirement. Exemplarily, the preset image quality requirement includes at least one of an SNR requirement, a brightness requirement, a contrast requirement, and other requirements related to the image quality. The processing device may determine the target image with the best SNR as the target display image; or the processing device may use a deep learning model to make comprehensive determination to select the target image with the best comprehensive quality as the target display image; or the processing device may determine the target display image through an alignment technique based on the motion of the scan region.

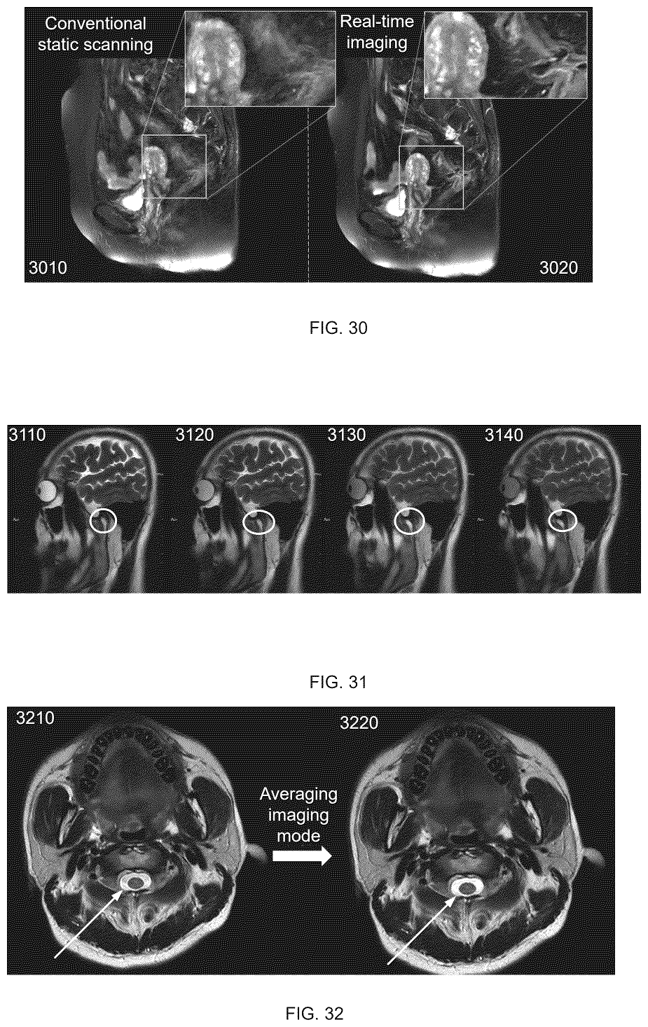

FIG. 30 is an exemplary schematic diagram of a target display image obtained in a static imaging mode according to some embodiments of the present disclosure. Image 3010 was acquired using conventional static scanning. Due to peristalsis in the rectum and uterus, the details of the uterine wall and rectal wall become blurred. In clinical practice, such cases require rescheduling the patient for another scan, and if the new scan fails, the patient must be administered a medication to suppress intestinal peristalsis, such as hyoscine butylbromide. Image 3020 is a target display image in the static imaging mode obtained using the MR real-time imaging provided by the present application. Because real-time imaging has a high temporal resolution that can freeze the motion of the uterus and rectum, it is possible to achieve clear imaging of the uterine endometrium and rectal wall.

In some embodiments, when the MRI model includes a static imaging model, the target display image is determined based on a volume of effective information for diagnosis. The volume of effective information for diagnosis is used to measure an extent to which an image is favorable for diagnosis.

In some embodiments, the processing device determines image characteristics of the target image to obtain the volume of effective information for diagnosis based on the image characteristics. The image characteristics such as SNR, contrast, etc. The higher the SNR, the greater the volume of effective information for diagnosis.

In some embodiments, the processing device determines the image characteristics of a region of interest (ROI) in the target image, and obtains the volume of effective information for diagnosis based on the image characteristics of the ROI. The ROI may be artificially set, and a manner of determining the volume of effective information for diagnosis may be the same as described above, which is not repeated here.

Exemplarily, the processing device selects the target image with the greatest volume of effective information for diagnosis as the target display image, or selects, as the target display image, any one of the target images with the volumes of effective information for diagnosis greater than a preset threshold.

In some embodiments, multiple target images are determined as the target display image when the MRI model is determined to include the dynamic imaging model.

In some embodiments, for each slice, the processing device may select multi-phase target images corresponding to the slice as the target display image corresponding to the slice in the dynamic imaging mode. For example, the reconstructed image includes target images 1-6, wherein target images 1-3 correspond to phases 1-3 and slice 1, and target images 4-6 correspond to phases 1-3 and slice 2. In the dynamic imaging mode, the processing device may select target images 1-3 as the target display image corresponding to slice 1, and select target images 4-6 as the target display image corresponding to slice 2.

The following description takes determination of the target display image corresponding to one slice in the dynamic imaging mode as an example.

Exemplarily, when the MRI model includes the dynamic imaging model, the processing device uses the multi-phase target images as the target display image corresponding to the dynamic imaging model.

FIG. 31 is a schematic diagram illustrating an exemplary magnetic resonance images in a dynamic imaging mode according to some embodiments of the present disclosure. FIG. 31 shows a schematic diagram of dynamic imaging of the temporomandibular joint (TMJ). Images 3110-3140 are reconstructed real-time images of different phases in temporal order, with the circled area indicating the temporomandibular joint.

Conventional static scanning can only produce an image of the temporomandibular joint fixed at a certain angle (i.e., an image from only one phase), and cannot capture the joint's motion as dynamic imaging does. However, the diagnosis of conditions such as temporomandibular joint disorders and joint dislocation relies heavily on dynamic imaging indicators. By using the dynamic imaging mode of real-time imaging, it is easy to obtain a movie-like sequence of the scanned region.

In some embodiments, for each slice, in response to determining that the MRI mode includes a high-definition imaging mode, the processing device generates an average scan image by performing averaging on the target images corresponding to the slice; and uses the average scan image as the target display image corresponding to the slice in the HD imaging mode. For example, the reconstructed image includes target images 1-6, wherein target images 1-3 correspond to phases 1-3 and slice 1, and target images 4-6 correspond to phases 1-3 and slice 2. In the HD imaging mode, the processing device may generate an average scan image 1 by performing averaging on the target images 1-3, and determine the average scan image 1 as the target display image corresponding to slice 1. The processing device may generate an average scan image 2 by performing averaging on the target images 4-6, and determine the average scan image 2 as the target display image corresponding to slice 2.

The following description takes determination of the target display image corresponding to one slice in the HD imaging mode as an example.

Exemplarily, when the MRI mode includes an averaging imaging mode (a high-definition imaging mode), the processing device averages the multi-phase target images to obtain an average scan image, and uses the average scan image as the target display image corresponding to the averaging imaging mode. The averaging process is to average of the multi-phase target images belonging to the same slice, thereby obtaining an averaged scan image of each slice. Then a target display image corresponding to the average imaging mode is obtained based on the average scan image of each slice.

Exemplarily, when performing the averaging, a mean value is determined for all phases of each slice, or the averaging is realized by determining a root mean square in a pixel-by-pixel manner, etc.

FIG. 32 is a schematic diagram illustrating an exemplary magnetic resonance image in a high-definition imaging mode according to some embodiments of the present disclosure. Image 3210 is a target image of one phase generated by a dynamic scan of the transverse cervical spine view, while image 3220 is an average scan image generated in the averaging imaging mode based on multi-phase target images of the transverse cervical spine view. In images 3210 and 3220, the areas indicated by the arrows represent the spinal cord. The user intends for the spinal cord to be entirely displayed with a highlighted signal. However, due to the flow void effect inherent in the FSE sequence, it cannot be ensured that the cerebrospinal fluid in each phase image exhibits a highlighted signal. By using the averaging imaging mode of real-time imaging, a highlighted spinal cord signal can be achieved.

The processing device, when generating the target display image corresponding to the MRI mode, may also output the target display image for display.

In operation 406, the processing device displays the target display image.

In some embodiments, the processing device sends the generated target display image corresponding to the MRI mode to a display device for output and display. The display device includes a display screen communicatively connected to the processing device, a wearable device communicatively connected to the processing device, etc. The wearable device includes a smartwatch, a smart bracelet, and a smart headset device, etc., and these wearable devices outputs the display target image based on an extended reality technology, etc. The embodiments of the present disclosure do not make specific limitations in this regard.

Exemplarily, the processing device outputs the target display image corresponding to the MRI model for display. When there are a plurality of MRI modes, the processing device displays the target display images corresponding to the plurality of MRI modes simultaneously or sequentially.

Optionally, when displaying the plurality of target display images corresponding to the plurality of MRI modes sequentially, the processing device displays the target display images corresponding to each MRI mode sequentially according to a preset time interval and a preset display sequence. Alternatively, the processing device displays the target display images corresponding to each MRI mode sequentially triggered by the user. For example, when the user triggers a next MRI mode, the processing device displays the target display image corresponding to the next MRI mode. When the user triggers a previous MRI mode, the processing device displays the target display image corresponding to the previous MRI mode.

In this embodiment, the processing device displays the target display image by obtaining the MRI mode and determines the target display image corresponding to the MRI mode based on the multi-phase target images, thereby displaying the target display image. That is, the MRI method proposed in the embodiments of the present disclosure satisfies the imaging requirements under a plurality of different imaging modes, and can be targeted according to the different requirements of the user, thereby improving a universality and a flexibility of the MRI.

Using the MRI method proposed in the embodiments of the present disclosure, on one hand, a target K-space dataset of an imaging object is determined. The generation of the target K-space dataset enables rapid and complete data collection, ensuring both the completeness of static imaging data and the temporal resolution required for dynamic imaging, thereby providing a data basis for subsequent image reconstruction. On the other hand, by determining a coil sensitivity map and using it to perform image reconstruction on the target K-space dataset, multi-phase target images are obtained. This data processing approach achieves high-quality image reconstruction and produces reconstructed images for multiple phases. Therefore, by employing the MRI method described in this disclosure, both static high-definition imaging and dynamic high-definition imaging requirements can be simultaneously met in a single scanning process. Moreover, the reconstructed multi-phase target images can be applied in various imaging modes to obtain target display images under different imaging conditions, thereby not only enhancing the efficiency of MRI but also improving the imaging quality to meet diverse clinical needs.

FIG. 5 is a flowchart illustrating an exemplary magnetic resonance imaging method according to some other embodiments of the present disclosure.

In operation 502, the processing device obtains at least one first K-space dataset from a plurality of K-space datasets corresponding to a plurality of phases of an imaging object.

At least one of the first K-space datasets is undersampled. Each K-space dataset corresponds to one of the plurality of phases.

In operation 504, for each of the at least one first K-space dataset, the processing device determines a target K-space dataset by filling, through reusing K-space data of at least one second K-space dataset, an undersampled region of the first K-space dataset. That is, the processing device may share the K-space data of the at least one second K-space dataset (e.g., at least one of K-space datasets other than the first K-space dataset in the plurality of K-space dataset) with the undersampled region of the first K-space dataset, so as to fill the undersampled region of the first K-space dataset with the shared K-space data of the at least one second K-space dataset, thereby determining the target K-space dataset.

The K-space position of the reused or shared K-space data of the at least one second K-space dataset corresponds to the K-space position of the undersampled region of the first K-space dataset. The at least one second K-space dataset is from the plurality of K-space datasets and corresponds to at least one phase different from the first K-space dataset.

After obtaining the first K-space dataset, the processing device performs a filling process on the undersampled region in the first K-space dataset to obtain the target K-space dataset.

The filling process includes using sampled data from at least one second K-space dataset corresponding to the undersampled region in the first K-space dataset to fill the undersampled region. The specific filling process can refer to the description provided in the above embodiment (for example, the process 200), where the undersampled region in the first K-space dataset is filled using at least one reference K-space dataset.

In operation 506, the processing device obtains a reconstruction mask, the reconstruction mask characterizing a weight and/or a phase corresponding to the reused K-space data of the at least one second K-space dataset.

The reconstruction mask is used to indicate the target weight and the phase interval corresponding to the process of filling the undersampled region of the first K-space dataset. The descriptions of the target weight and the phase interval may be referred to the specific descriptions in the above embodiments, which is not repeated herein.

For example, a first K-space dataset (corresponding to phase 1) includes undersampled sub-regions 1 and 2, and the undersampled sub-region 1 is filled using the fully sampled K-space data at a corresponding K-space position in a second K-space dataset 1 (corresponding to phase 2), and the undersampled sub-region 2 is filled using the fully sampled K-space data at a corresponding K-space position in a second K-space dataset 2 (corresponding to phase 3). The reconstruction mask corresponding to the first K-space dataset includes the target weight and/or the phase (phase 2, or a phase interval between phases 1 and 2) corresponding to the second K-space dataset 1 that is used to fill the undersampled sub-region 1, and the target weight and/or the phase (phase 3, or a phase interval between phases 1 and 3) corresponding to the second K-space dataset 2 that is used to fill the undersampled sub-region 2.

In operation 508, the processing device generates a reconstructed image of the imaging object based on the reconstruction mask and the target K-space dataset.

After obtaining the reconstruction mask, the processing device is able to determine the undersampled region in the filled K-space data based on the reconstruction mask, and fills the undersampled region in the filled K-space data again to obtain final fully sampled K-space data. The processing device further performs the image reconstruction on the final fully sampled K-space data, and obtains an MRI image of the imaging object. Optionally, a Fourier transform may be performed on the fully-sampled K-space data to obtain an MR image of the imaging object.

In some embodiments, an iterative reconstruction is performed on the target K-space dataset. Inputs to the iterative reconstruction include the target K-space dataset and the corresponding reconstruction mask. A manner for the iterative reconstruction includes an iterative self-consistent parallel imaging reconstruction (SPIRIT) algorithm, a SENSE algorithm, etc.

In some embodiments, by using the reconstruction mask to reconstruct the target K-space dataset to obtain the magnetic resonance image of the imaging object, a mis-matching (which leads to a data error,) of the filled K-space data in the target K-space dataset during the reconstruction process is avoided, thus improving an accuracy of the final fully sampled K-space data, and improving quality of the magnetic resonance image of the imaging object.

Detailed descriptions of the operations shown in FIG. 5 may be found in the related descriptions of FIGS. 2-3, which is not repeated here.

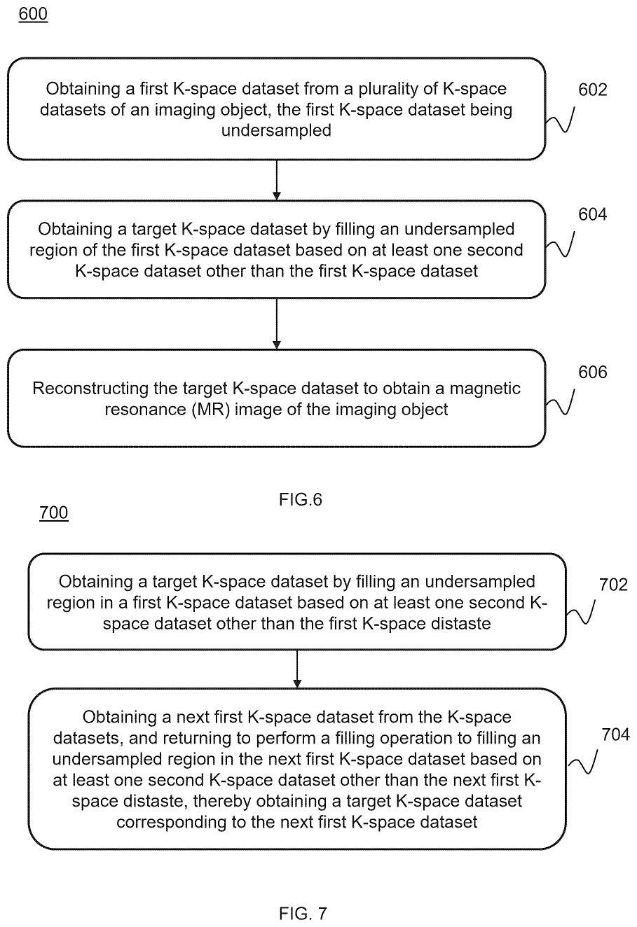

FIG. 6 is a flowchart illustrating an exemplary magnetic resonance imaging method according to some embodiments of the present disclosure. The process 600 is performed by an MRI system (e.g., the processing device 140).

In operation 602, the processing device obtains a first K-space dataset from a plurality of K-space datasets of an imaging object, the first K-space dataset being undersampled.

In operation 604, the processing device obtains a target K-space dataset by filling an undersampled region of the first K-space dataset based on at least one second K-space dataset other than the first K-space dataset.

In operation 606, the processing device reconstructs the target K-space dataset to obtain a magnetic resonance image (a target image) of the imaging object.

Detailed descriptions of each operation of FIG. 6 may be found in the descriptions of FIGS. 2-5.

FIG. 7 is a flowchart illustrating an exemplary filling process according to some embodiments of the present disclosure. The filling manner is a manner of obtaining a target K-space dataset by filling an undersampled region of a first K-space dataset based on at least one second K-space dataset other than the first K-space dataset.

In operation 702, the processing device obtains a target K-space dataset by filling an undersampled region in the first K-space dataset based on at least one second K-space dataset other than the first K-space distaste.

In operation 704, the processing device obtains a next first K-space dataset from the K-space datasets, and return to perform the operation of filling the undersampled region in the first K-space dataset based on at least one second K-space dataset other than the first K-space distaste to obtain the target K-space dataset.

Detailed descriptions of each operation of FIG. 7 may be found in the descriptions of FIGS. 2-5.

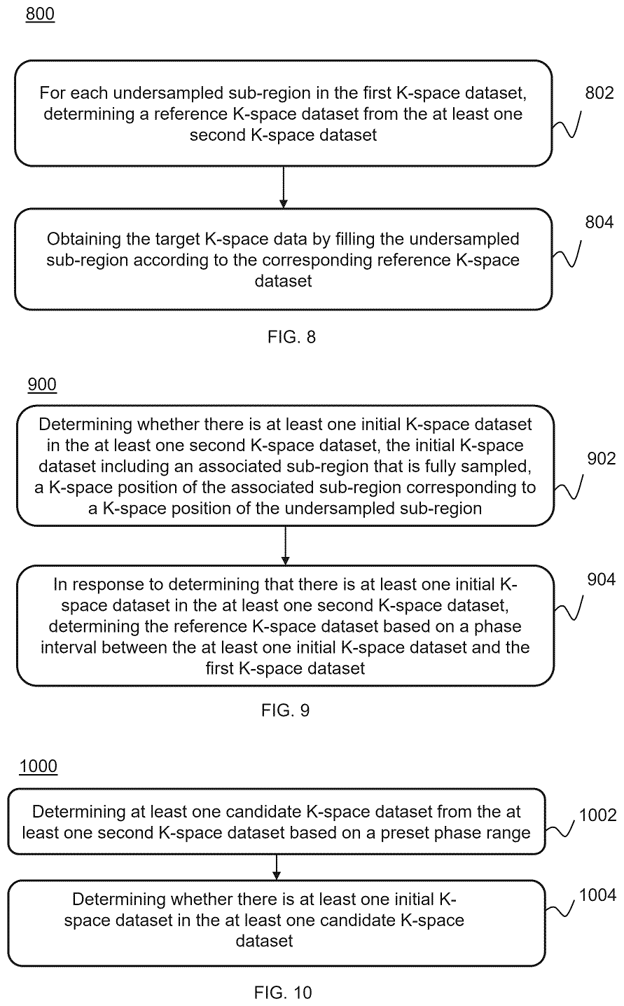

In some embodiments, the undersampled region of the first K-space dataset includes a plurality of undersampled sub-regions. FIG. 8 is a flowchart illustrating an exemplary filling process according to some other embodiments of the present disclosure.

In operation 802, for each undersampled sub-region in the first K-space dataset, the processing device determines a reference K-space dataset from the at least one second K-space dataset.

In operation 804, the processing device obtains the target K-space dataset by filling the undersampled sub-region according to the corresponding reference K-space dataset.

Detailed descriptions of each operation of FIG. 8 may be found in the descriptions of FIGS. 2-5.

In some embodiments, the processing device determines multiple undersampled sub-regions in the first K-space dataset, assigns numbers to the undersampled sub-regions, and sequentially iterates through each undersampled sub-region. For each undersampled sub-region, a reference K-space dataset is determined from at least one second K-space dataset; the undersampled sub-region is then filled based on the reference K-space dataset. This process continues until all of the undersampled sub-regions in the first K-space dataset have been processed, resulting in the target K-space dataset.

FIG. 9 is a flowchart illustrating an exemplary process for determining a target K-space dataset according to some embodiments of the present disclosure.

In operation 902, the processing device determines whether there is at least one initial K-space dataset in the at least one second K-space dataset. The initial K-space dataset includes an associated sub-region that is fully sampled, and a K-space position of the associated sub-region corresponds to a K-space position of the undersampled sub-region.

In operation 904, in response to determining that there is at least one initial K-space dataset in the at least one second K-space dataset, the processing device determines the reference K-space dataset based on a phase interval between each of the at least one initial K-space dataset and the first K-space dataset.

In some embodiments, determining the initial K-space dataset from the second K-space dataset includes the following operations.

In S1, the processing device sequentially traverses the K-space data in the second K-space datasets according to the phase interval between the second K-space datasets and the first K-space dataset, and determines whether the traversed K-space data includes an associated sub-region (e.g., a fully sampled K-space line).

The processing device sequentially iterates in order from the nearest to the farthest phase interval; if the phase intervals are the same, it gives priority to traversing the second K-space dataset that is acquired later in the first K-space dataset.

In S2, if the currently traversed second K-space dataset includes a fully-sampled target K-space line corresponding to the undersampled sub-region, the undersampled sub-region is filled based on the fully-sampled K-space line in the currently traversed second K-space dataset to obtain a target K-space line.

In S3, the currently traversed second K-space dataset does not include a fully-sampled K-space line corresponding to the undersampled sub-region, the processing device may traverse the next second K-space dataset until all second K-space datasets have been traversed.

Detailed descriptions of each operation of FIG. 9 may be found in the descriptions of FIGS. 2-5.

FIG. 10 is a flowchart illustrating an exemplary process for determining an initial K-space dataset according to some embodiments of the present disclosure.

In operation 1002, the processing device determines at least one intermediate second K-space dataset (also referred to as candidate K-space dataset) from at least one second K-space dataset according to a preset phase range.

The preset phase range can be set and stored on the terminal by the user according to the actual application scenario. For example, the preset phase range may be set based on the motion state of the imaging object. If the imaging object is moving slowly or is almost stationary, considering that the phase differences are relatively small in such relatively stationary state and can be freely shared, the preset phase range can be set to a larger value (e.g., the preset phase range is 80% or 100%). Conversely, if the imaging object's motion state changes significantly, in order to prevent erroneous information sharing due to mismatches between different phases, the preset phase range can be set to a smaller value (e.g., the preset phase range is 20%).

The processing device determines at least one intermediate second K-space dataset from at least one second K-space dataset based on the preset phase range; that is, the K-space data within the preset phase range in the at least one second K-space dataset are identified as the at least one intermediate second K-space dataset.

In operation 1004, the processing device determines whether at least one initial K-space dataset exists in the at least one intermediate second K-space dataset.

After determining the at least one intermediate second K-space dataset from the at least one second K-space dataset, the processing device analyzes the at least one intermediate second K-space dataset to determine whether at least one initial K-space dataset is present within the at least one intermediate second K-space dataset.

In this embodiment, at least one intermediate second K-space dataset is determined from the at least one second K-space dataset by setting the preset phase range, and then the processing device determines whether at least one initial K-space dataset exists within the at least one intermediate second K-space dataset. This ensures that the MRI method provided by the present disclosure is applicable to the magnetic resonance image reconstruction of the imaging object with different motion states, thereby improving the applicability and reliability of the MRI method.

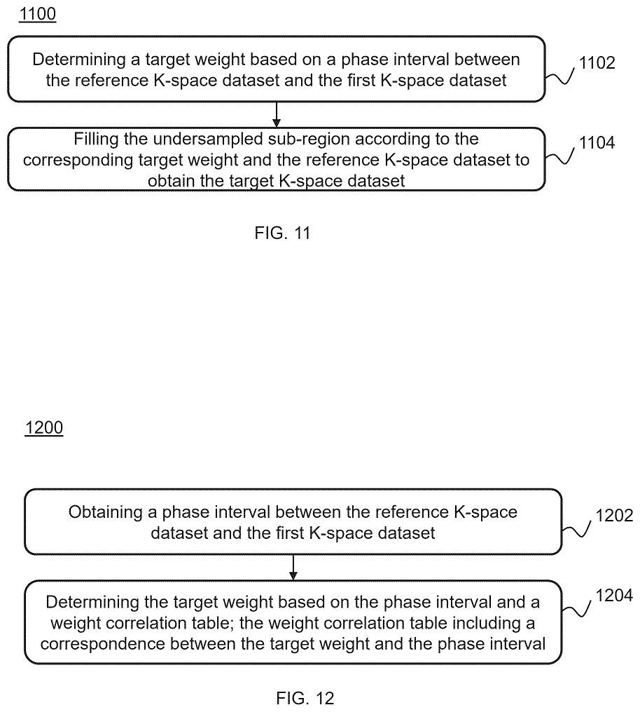

Detailed descriptions of each operation of FIG. 11 may be found in the descriptions of FIGS. 2-5.

FIG. 11 is a flowchart illustrating a process for filling an undersampled sub-region according to some embodiments of the present disclosure.

In operation 1102, the processing device determines a target weight based on a phase interval between the reference K-space dataset and the first K-space dataset.

In operation 1104, the processing device fills the undersampled sub-region according to the corresponding target weight and the reference K-space dataset to obtain the target K-space dataset.

Detailed descriptions of each operation of FIG. 11 may be found in the descriptions of FIGS. 2-5.

FIG. 12 is a flowchart illustrating a process for determining a target weight according to some embodiments of the present disclosure.

In operation 1202, the processing device determines a phase interval between the reference K-space dataset and the first K-space dataset.

In operation 1204, the processing device determines the target weight based on the phase interval and a weight correlation table; the weight correlation table including a correspondence between the target weight and the phase interval.

In some embodiments, the processing device may obtain a reconstruction mask, and obtain a magnetic resonance image (a target image) by reconstructing the K-space dataset using the reconstruction mask. The reconstruction mask includes the target weight and/or a phase corresponding to the K-space data that is used to fill the undersampled sub-regions of the first K-space dataset.

Detailed descriptions of each operation of FIG. 12 may be found in the descriptions of FIGS. 2-5.

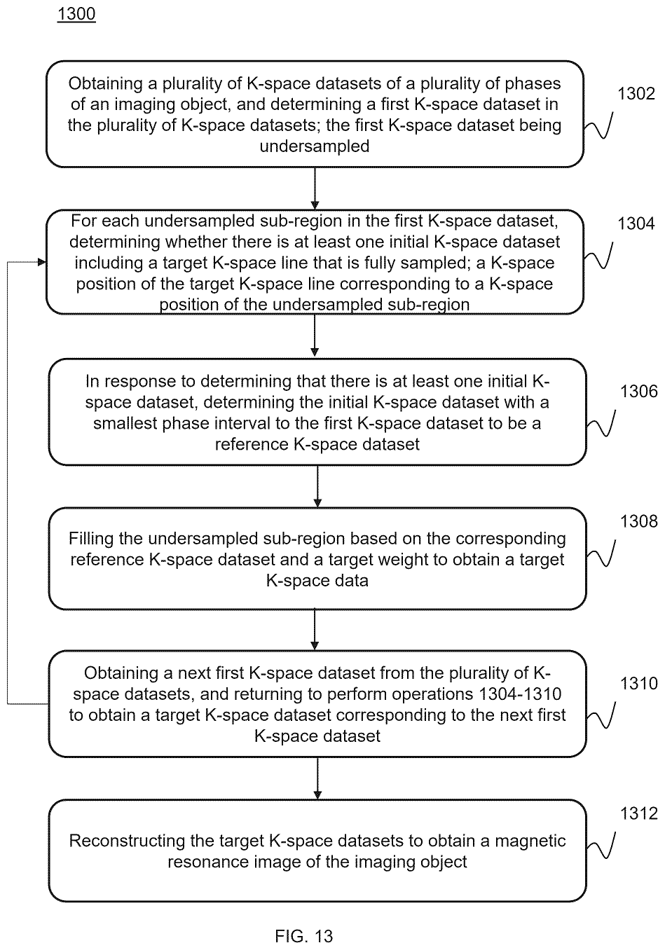

FIG. 13 is a flowchart illustrating an exemplary magnetic resonance imaging method according to some other embodiments of the present disclosure.

In operation 1302, the processing device obtains a plurality of K-space datasets of a plurality of phases of an imaging object and determines a first K-space dataset in the plurality of K-space datasets. The first K-space dataset is undersampled.

In operation 1304, for each undersampled sub-region in the first K-space dataset, the processing device determines whether there is at least one initial K-space dataset including a fully sampled K-space line (an associated sub-region) corresponding to the undersampled sub-region. A K-space position of the fully sampled K-space line corresponds to a K-space position of the undersampled sub-region.

In operation 1306, in response to determining that there is at least one initial K-space dataset, the processing device determines the initial K-space dataset with the smallest phase interval to the first K-space dataset to be a reference K-space dataset.

In operation 1308, the processing device fills the undersampled sub-region based on the corresponding reference K-space dataset and a target weight to obtain a target K-space dataset.

The target weight is determined based on the phase interval between the reference K-space dataset and the first K-space dataset.

FIG. 14 is a schematic diagram illustrating an exemplary target K-space dataset according to some embodiments of the present disclosure. In FIG. 14, white regions represent actual sampled regions, gray regions represent K-space data obtained by filling undersampled sub-regions according to the method provided by the present disclosure, and black regions represent the undersampled sub-regions which are still unfilled after traversing all the second K-space datasets.

In operation 1310, the processing device obtains a next first K-space dataset from the K-space datasets, and returns to perform operations 1304-1310 based on the next first K-space dataset to obtain the corresponding target K-space dataset.

In operation 1312, the processing device reconstructs the target K-space datasets to obtain a magnetic resonance image of the imaging object.

FIG. 15 is a schematic diagram illustrating exemplary interleaved sampling according to some embodiments of the present disclosure. For example, as shown in FIG. 15, which illustrates the sampling trajectories of eight K-space datasets corresponding to phases 1-8, respectively, the white regions refer to the sampled regions, and the black regions refer to the unsampled regions. As shown in FIG. 15, for each phase, a sampling density in the central region of K-space is greater than a sampling density in the non-central regions of K-space, and the sampling trajectories of the 8 K-space datasets are complementary and interleaved in the phase direction.

As shown in FIG. 16, taking 4-phase highly accelerated head magnetic resonance dynamic data (the first K-space datasets) as an example, FIG. 16 shows the images obtained by directly performing inverse Fourier transform on the first K-space datasets corresponding to the 4 phases. It can be seen that each image has very serious aliasing artifacts and noise. After the first K-space datasets corresponding to the four phases are filled and reconstructed using the reconstruction manner (e.g., the process 200) proposed in the present disclosure, the resultant images are shown in FIG. 17. It can be seen that the images in FIG. 17 have no aliasing artifacts and noise, and the image quality is higher.

Detailed descriptions of each operation of FIG. 13 may be found in the descriptions of FIGS. 2-5.

FIG. 18 is a flowchart illustrating an exemplary magnetic resonance imaging method according to some other embodiments of the present disclosure.

In operation 1802, the processing device obtains a plurality of K-space datasets corresponding to a plurality of phases of an imaging object, and at least one first K-space dataset of the plurality of K-space datasets is undersampled. Different phases correspond to different sampling times, respectively.

Description of the K-space datasets of the imaging object, and descriptions of the first K-space dataset may be referred to in the specific descriptions in the above embodiments, which is not repeated here.

In operation 1804, the processing device performs a filling process for the at least one first K-space dataset to obtain a target K-space dataset.

The filling process includes reusing or sharing the sampled data from at least one second K-space dataset at the same K-space position as the undersampled sub-region to fill the undersampled region in the first K-space dataset, i.e., using K-space data of the associated sub-region in the reference K-space dataset to fill the corresponding undersampled sub-region in the first K-space dataset.

In operation 1806, the processing device obtains a reconstruction mask, the reconstruction mask characterizing a target weight and/or a phase of the reused or shared K-space data configured to fill the undersampled sub-region.

Descriptions of the reconstruction mask, the target weight and the phase of the reused or shared K-space data may be found in the specific descriptions in the above embodiments, which are not repeated here.

The processing device obtains the reconstruction mask corresponding to the target K-space dataset.

In operation 1808, the processing device reconstructs the target K-space dataset using the reconstruction mask to obtain a magnetic resonance image (a target image) of the imaging object.

After obtaining the reconstruction mask, the processing device uses the reconstruction mask to reconstruct the target K-space dataset to obtain the magnetic resonance image of the imaging object. Descriptions of reconstructing the target K-space dataset using the reconstruction mask may be found in the specific descriptions in the embodiments described above, which is not repeated herein.

In this embodiment, for the first K-space dataset in the K-space datasets of the imaging object, the undersampled region is filled by reusing or sharing the sampling data at the same K-space position from at least one second K-space dataset, that is, by sharing the K-space data of multiple phases, to obtain the target K-space dataset. This approach can effectively utilize the temporal and spatial information (spatiotemporal information sharing). Compared with existing dynamic MRI methods, even under high acceleration undersampling conditions, the undersampled region in the first K-space dataset can be filled, thereby maintaining high spatiotemporal resolution while improving the quality of the reconstructed MRI image. Moreover, by using a reconstruction mask to reconstruct the filled K-space data, the MRI image of the imaging object is obtained. This process avoids mismatching of the data that have already been filled during subsequent filling processes, ensuring the accuracy of the final fully-sampled K-space data and further improving the quality of the resultant MRI image.

Some embodiments described herein provide an MRI method by acquiring the first K-space dataset from the K-space datasets of the imaging object, wherein the first K-space dataset is undersampled; then the processing device fills the undersampled region in the first K-space dataset based on the second K-space dataset (other than the first K-space dataset) to obtain the target K-space dataset; and the processing device reconstructs the target K-space dataset to obtain the MRI image of the imaging object. In this embodiment, for the undersampled region in the first K-space dataset, the second K-space dataset is used for filling the first K-space dataset to obtain the target K-space dataset (i.e., the K-space data of each phase are shared), from which the MRI image of the imaging object is reconstructed. This method efficiently utilizes the temporal and spatial redundancy (spatiotemporal information sharing). Compared with conventional dynamic MRI methods, this method enables the undersampled region of the first K-space dataset to be filled even under high acceleration undersampling, thereby simultaneously preserving high spatiotemporal resolution and improving the quality of the reconstructed MRI image.

In some embodiments, the operations of the magnetic resonance reconstruction method further include: displaying the magnetic resonance image of the imaging object in a display interface. The magnetic resonance image of the imaging object is a static image or a dynamic image. The static image is the reconstructed image of one phase or an averaged reconstructed image of a plurality of phases. The dynamic image is the reconstructed image of a plurality of phases displayed in a sequence of sampling time.

The processing device includes a display, and after obtaining the magnetic resonance image of the imaging object, the processing device displays the magnetic resonance image on the display interface of the display. The reconstructed image for each phase may be displayed on the display interface, or the averaged reconstructed image corresponding to an average of the reconstructed images of a plurality of phases, or the dynamic image, may be displayed on the display interface. The dynamic image refers to a reconstructed image of the plurality of phases displayed dynamically with the sampling time.

In this embodiment, the magnetic resonance image of the imaging object is displayed on an interface, facilitating user observation and enhancing the practicality of the MRI method.

Detailed descriptions of each operation of FIG. 18 may be found in the descriptions of FIGS. 2-5.

It should be appreciated that although the each operation in the flowcharts involved in the embodiments as described above are shown sequentially as indicated by the arrows, the operations are not necessarily executed sequentially in the order indicated by the arrows. Unless expressly stated herein, there is no strict order limitation on the execution of these operations, and the operations may be executed in other orders. Moreover, at least a part of the operations in the flowchart involved in the embodiments as described above may include a plurality of operations or a plurality of stages, which are not necessarily executed to completion at the same moment, but are be executed at different moments, and the order in which these operations or stages are executed is not necessarily sequential, but are executed in turn or alternately with other operations or at least a part of the operations or the stages in other operations.

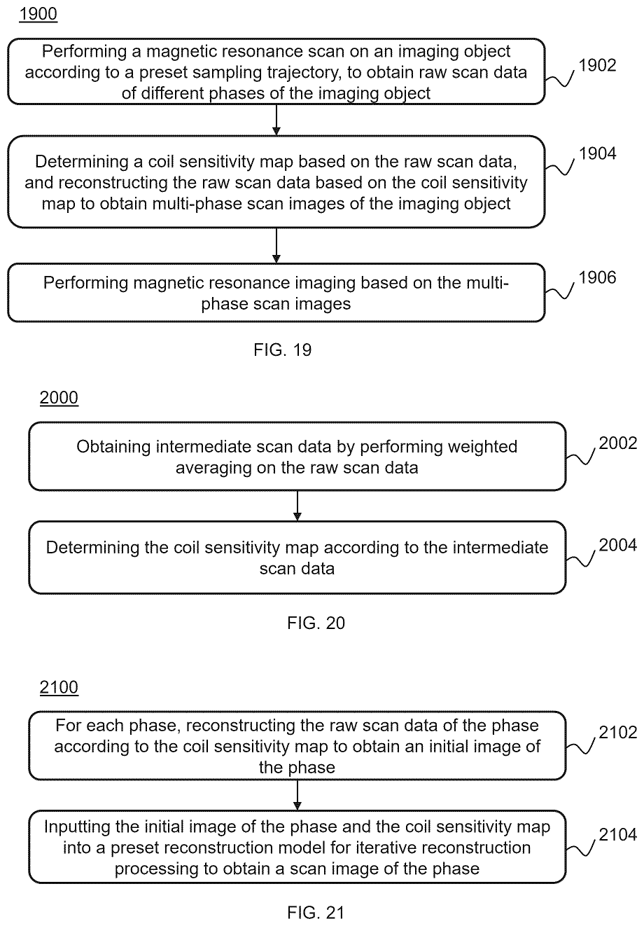

FIG. 19 is a flowchart illustrating an exemplary magnetic resonance imaging method according to some embodiments of the present disclosure. In some embodiments, the process 1900 is performed by an MRI system (e.g., the processing device 140).

In operation 1902, the processing device performs a magnetic resonance scan on an imaging object according to a preset sampling trajectory, to obtain raw scan data of different phases of the imaging object.

The raw scan data for the different phases includes scan data for different slices of the imaging object. That is to say, the raw scan data of the different phases may correspond to the same or different slices of the imaging object. Exemplarily, a sum of the raw scan data for the different phases encompasses the scan data for all slices of the imaging object.

In an optional implementation, the preset sampling trajectory is complementary and interlaced in a phase direction. An acceleration factor in a central region of K-space is less than a first factor threshold, and an acceleration factor in a non-central region of K-space is greater than a second threshold. The first factor threshold is less than or equal to the second factor threshold. Using the complementary and interlaced sampling trajectory, complementary interlaced K-space datasets may be scanned. For example, assuming that the scanning phase includes a first phase and a second phase, the sampling trajectory is that the first phase acquires data of the first slice, the third slice, the fifth slice, and other odd slices, and the second phase acquires data of the second slice, fourth slice, sixth slice and other even slices. Assuming that the scanning phase is more than two phases, the corresponding slices of each phase are spatially interlaced or complementary, e.g., the first phase acquires the data of the first slice, the fourth slice, the seventh slice, etc., the second phase acquires the data of the second slice, the fifth slice, the eighth slice, etc., and a third phase acquires the data of the third slice, the sixth slice, the ninth slice, etc. Of course, for multiple phases, the acquired slice data also includes the scan data of the same slice, and the embodiments of the present disclosure do not make specific limitations in this regard.

Exemplarily, when the preset sampling trajectory is determined, a magnetic resonance scan of the imaging object is performed based on the preset sampling trajectory, thereby obtaining the raw scan data of the plurality of phases of the imaging object. The raw scan data of each phase includes the scan data of at least one slice of the imaging object. Optionally, the raw scan data for each phase may be scanning data obtained through undersampling with a high acceleration factor.

In some embodiments, the preset sampling trajectory is also the preset sampling trajectory described in the operation 202 in FIG. 2.

In some embodiments, the plurality of K-space datasets illustrated in FIG. 2 can be used as the raw scan data.

In operation 1904, the processing device determines a coil sensitivity map based on the raw scan data of each phase, reconstructs the raw scan data of the each phase based on the coil sensitivity map, and obtains multi-phase scanning images of the imaging object.

In operation 1906, the processing device performs magnetic resonance imaging based on the multi-phase scan images.

Detailed descriptions of each operation of FIG. 19 may be found in the descriptions of FIGS. 2-4.

FIG. 20 is a flowchart illustrating an exemplary process for determining a coil sensitivity map according to some embodiments of the present disclosure.

In operation 2002, the processing device obtains intermediate scan data by performing weighted averaging on the raw scan data of each phase.

In operation 2004, the processing device determines the coil sensitivity map according to the intermediate scan data.

Detailed descriptions of each operation of FIG. 20 may be found in the descriptions of FIG. 3.

FIG. 21 is a flowchart illustrating an exemplary process for obtaining multi-phase scan images according to some embodiments of the present disclosure.

In operation 2102, for each phase, the processing device reconstructs the raw scan data of the phase according to the coil sensitivity map to obtain an initial image of the phase.

In operation 2104, the processing device inputs the initial image of the phase and the coil sensitivity map into a preset reconstruction model for iterative reconstruction processing to obtain a scan image of the phase.

Detailed descriptions of each operation of FIG. 21 may be found in the descriptions of FIG. 2.

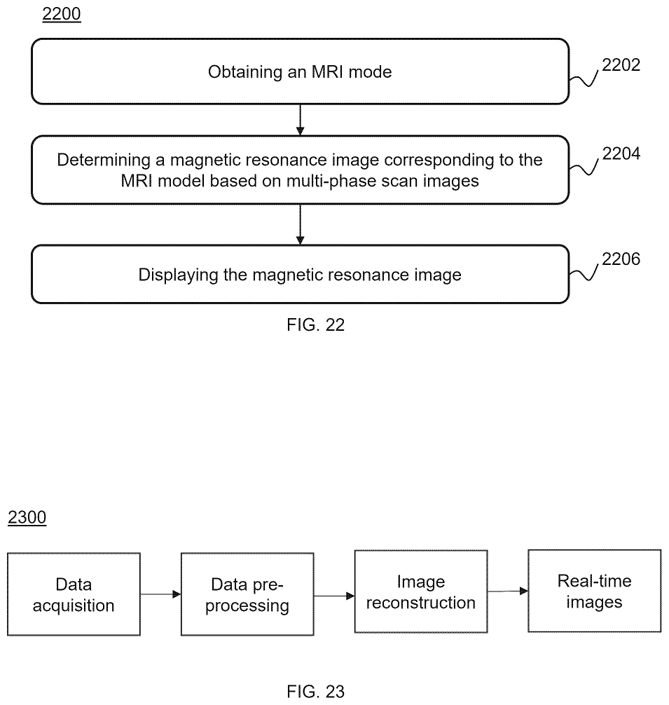

FIG. 22 is a flowchart illustrating an exemplary process for displaying a magnetic resonance image according to some embodiments of the present disclosure.

In operation 2202, the processing device obtains an MRI mode.

In operation 2204, the processing device determines a magnetic resonance image corresponding to the MRI model based on multi-phase scan images.

In operation 2206, the processing device displays the magnetic resonance image.

Detailed descriptions of each operation of FIG. 22 may be found in the descriptions of FIG. 4.

Referring to FIG. 23, FIG. 23 is a flow chart illustrating an exemplary magnetic resonance imaging method according to some embodiments of the present disclosure.

### Step 1, Data Acquisition

Unlike conventional static MRI sampling trajectories, real-time imaging in this embodiment acquire K-space data using a specially designed sampling trajectory. This trajectory is interleaved complementary along the phase dimension, and the acceleration factor is lower in the low-frequency central region of the K-space and higher in the high-frequency non-central regions. After scanning with this specially designed sampling trajectory, multiple sets of raw scan data for different phases can be obtained, and the raw scan data for each phase include scan data from different slices.

Additionally, it should be noted that by employing a lower acceleration factor in the low-frequency central region of K-space and a higher acceleration factor in the high-frequency non-central regions, more data from the low-frequency region can be acquired while acquiring fewer data from the high-frequency region. This approach not only ensures the integrity of the acquired data to maintain the resolution of the reconstructed images but also improves data acquisition efficiency.

### Step 2, Data Preprocessing

After data acquisition using the preset sampling trajectory, the raw scan data for each phase are highly undersampled. At this point, a series of image preprocessing steps are required to obtain an initially reconstructed dataset before proceeding with subsequent iterative reconstruction. Optionally, the acquired raw scan data can be subjected to a weighted average along the temporal dimension (that is, for each slice of data, a weighted average is taken over the same slice across multiple phases) to obtain a fully sampled K-space dataset. Based on this fully sampled K-space dataset, a coil sensitivity map can be derived. Using the coil sensitivity map, the raw scan data for each phase can be initially reconstructed to yield an initial image corresponding to each phase. These initial images, along with the coil sensitivity map, are then used as input to an image reconstruction model, ultimately resulting in the final reconstructed image for each phase.

### Step 3, Image Reconstruction

The image reconstruction can employ a physics-model-based deep learning iterative reconstruction module. This module may comprise two components: a data consistency term and a deep learning network. For each phase, the initial image for the phase along with the coil sensitivity map are input into the deep learning iterative reconstruction module for iterative processing. After a series of iterative reconstructions, a high-definition, artifact-free scan image corresponding to the phase can be obtained.

### Step 4, Real-Time Images

After the iterative reconstruction through the image reconstruction module, multi-phase scan images (also referred to as real-time images) are obtained. These multi-phase images can be displayed in three imaging modes: “static imaging mode,” “dynamic imaging mode,” and “averaging imaging mode.” The user can switch between these different imaging modes according to their needs. When a static image is desired, an image of one particular phase from the multi-phase images can be selected (static imaging mode). When the user wishes to observe the dynamic imaging process, the multi-phase images can be played continuously in a loop (dynamic imaging mode, also known as a movie mode). Additionally, the user can process the multi-phase images using an averaging method to obtain an image with a higher signal-to-noise ratio (averaging imaging mode, also referred to as a high-definition mode).

With these three real-time imaging modes available, the user can either view a static image from a single phase or assess the motion state within the scanned region by observing the continuous changes across all phases, thereby providing activity indicators for clinical diagnosis.

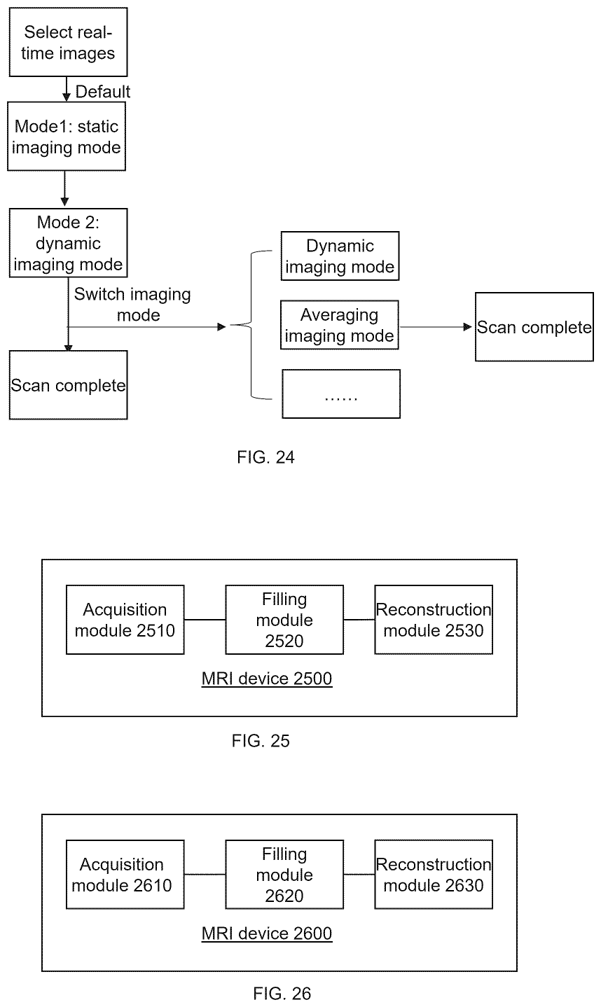

FIG. 24 is a schematic diagram illustrating an exemplary imaging display manner according to some embodiments of the present disclosure. Exemplary, during an MRI scan, both static and dynamic imaging may be performed by default. In other words, the processing device can determine the MR images corresponding to the static imaging mode and dynamic imaging mode based on the multi-phase scan images, and then output these MR images for display.

Furthermore, if the user wishes to view MR images corresponding to a different imaging mode, a new MR image corresponding to the switched imaging mode can be obtained. For example, the processing device may output the MR images corresponding to the default two imaging modes as well as the MR image corresponding to the new mode simultaneously. Alternatively, the default static imaging mode's MR image may be replaced by the MR image corresponding to the new mode (e.g., HD imaging mode), so that the interface displays the new mode's MR image together with the dynamic imaging mode's MR image. In another scenario, the default dynamic imaging mode's MR image may be replaced by the MR image corresponding to the new mode (e.g., HD imaging mode), with the interface then displaying the new mode's MR image along with the static imaging mode's MR image.

It should be noted that for the default static imaging mode, the static MR image may be obtained using conventional static imaging techniques or by employing an artificial intelligence method based on deep learning.

It should be appreciated that although the individual operations in the flowcharts involved in the embodiments as described above are shown sequentially as indicated by the arrows, the operations are not necessarily executed in the sequence indicated by the arrows. Unless expressly stated herein, there is no strict order limitation on the execution of these operations, and the operations may be executed in some other order. Moreover, at least a part of the operations in the flowchart involved in the embodiments as described above may include a plurality of operations or a plurality of stages, which are not necessarily executed to completion at the same moment, but may be executed at different moments, and the order in which these operations or phases are executed is not necessarily sequential, but may be executed in turn or alternately with other operations.

Based on the same inventive conception, embodiments of the present disclosure also provide a magnetic resonance imaging device for realizing the magnetic resonance imaging method covered above. The realization of the problem solving provided by this device is similar to the realization documented in the above-described method, and therefore the specific limitations in the one or more embodiments of the magnetic resonance imaging device provided below can be found in the above description for the limitations of the magnetic resonance imaging method and will not be repeated herein.

FIG. 25 is a structural diagram illustrating an exemplary magnetic resonance imaging device according to some embodiments of the present disclosure. The magnetic resonance imaging device 2500 includes: an acquisition module 2510, a filling module 2520, and a reconstruction module 2530. The magnetic resonance imaging device 2500 may be implemented on the processing device 140 through either software or hardware. The magnetic resonance imaging device 2500 may be used to perform the processes in FIGS. 2-13, FIG. 18, and FIGS. 22-24.

The acquisition module 2510 is configured to acquire a first K-space dataset in K-space datasets of an imaging object; and the first K-space dataset is undersampled.

The filling module 2520 is configured to fill an undersampled region of the first K-space dataset according to at least one second K-space dataset to obtain a target K-space dataset.

The reconstruction module 2530 is configured to reconstruct the target K-space dataset to obtain a magnetic resonance image of the imaging object.

In some embodiments, the filling module 2520 includes a first filling unit and a second filling unit. The first filling unit is used to fill the undersampled region of the first K-space dataset based on the at least one second K-space dataset to obtain the target K-space data. The second filling unit is used to obtain a next first K-space dataset from the K-space datasets, and return to perform the filling operation to obtain a target K-space dataset corresponding to the next first K-space dataset.

In some embodiments, the first filling unit includes a data determination unit and a sub-region filling unit. The data determination unit is used to determine, for each undersampled sub-region in the first K-space dataset, a reference K-space dataset from the at least one second K-space dataset. The sub-region filling unit is used to fill each undersampled sub-region according to the corresponding reference K-space dataset to obtain the target K-space dataset.

In some embodiments, the data determining unit includes a first determination sub-unit and a second determination sub-unit. The first determination sub-unit is used to determine whether there is at least one initial K-space dataset in the at least one second K-space dataset. The initial K-space dataset includes a fully-sampled target K-space line, and a position of the target K-space line corresponds to a position of an undersampled sub-region. The second determination sub-unit is used to determine, in response to determining that there is at least one initial K-space dataset in the at least one second K-space dataset, a reference K-space dataset based on a phase interval between the at least one initial second K-space dataset and the first K-space dataset.

In some embodiments, the first determination sub-unit is used to determine at least one candidate K-space dataset from the at least one second K-space dataset based on a preset phase range; and to determine whether there is at least one initial second K-space dataset in the at least one candidate K-space dataset.

In some embodiments, the sub-region filling unit is used to determine a target weight based on the phase interval between the reference K-space dataset and the first K-space dataset; and to fill the undersampled sub-region based on the corresponding target weight and the corresponding reference K-space dataset to obtain the target K-space dataset.

In some embodiments, the sub-region filling unit is further used to obtain the phase interval between the reference K-space dataset and the first K-space dataset; to determine the target weight based on the phase interval and a weight correlation table. The weight correlation table includes a relationship between the target weight and the phase interval.

In some embodiments, the magnetic resonance imaging device 2500 further includes a display module. The display module is used to display the magnetic resonance image of the imaging object on a display interface. The magnetic resonance image of the imaging object is a static image or a dynamic image. The static image is a reconstructed image of a phase or an averaged reconstructed image of a plurality of phases. The dynamic image is multi-phase scan images displayed in an order of sampling time.

Processes performed by modules of the magnetic resonance imaging device 2500 are detailed in the descriptions in FIGS. 2-13, FIG. 18, and FIGS. 22-24.

The various modules in the above-described magnetic resonance imaging device may be realized, in whole or in part, by software, hardware, and combinations thereof. The various modules described above may be embedded in a hardware form in or independently from a processor in a computer device, or may be stored in a software form in a memory in the computer device so as to be invoked by the processor to perform the various modules described above.

FIG. 26 is a structural diagram illustrating an exemplary magnetic resonance imaging device according to some embodiments of the present disclosure. The device 2600 includes: an acquisition module 2610, a filling module 2620, and a reconstruction module 2630. The magnetic resonance imaging device 2600 is implemented on the processing device 140 in software or hardware. The magnetic resonance imaging device 2600 may be used to perform the processes in FIGS. 2-13, FIG. 18, and FIGS. 22-24.

The acquisition module 2610 is configured to obtain K-space datasets of a plurality of phases of an imaging object. The K-space datasets include at least one first K-space dataset obtained by undersampling. Different phases correspond to different sampling times.

The filling module 2620 is configured to perform a filling process for the at least one first K-space dataset to obtain a target K-space dataset. The filling process includes filling an undersampled region in the first K-space dataset by reusing sharing the sampling data at the same K-space positions in the second K-space dataset.

The obtaining module 2610 is further configured to obtain a reconstruction mask. There reconstruction mask characterizes a target weight and/or a phase of the reused or shared sampling data.

The reconstruction module 2630 is configured to reconstruct the target K-space dataset using the reconstruction mask to obtain a magnetic resonance image of the imaging object.

In some embodiments, the magnetic resonance imaging device 2600 further includes a display module. The display module is used to display the magnetic resonance image of the imaging object on a display interface. The magnetic resonance image of the imaging object is a static image or a dynamic image. The static image is a reconstructed image of a phase or an averaged reconstructed image of a plurality of phases. The dynamic image is multi-phase scan images displayed in an order of sampling time.

The processes performed by the magnetic resonance imaging device 2600 are described in detail in FIGS. 2-13, FIG. 18, and FIGS. 22-24.

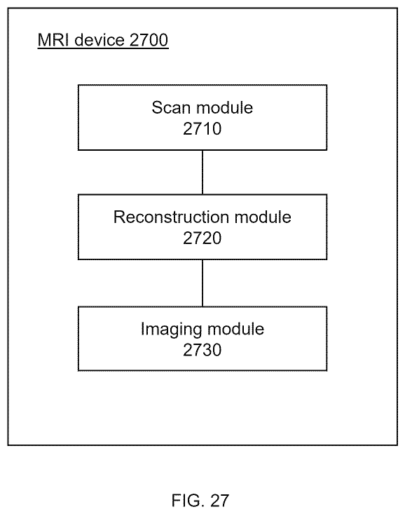

FIG. 27 is a structural diagram illustrating an exemplary magnetic resonance imaging device according to some embodiments of the present disclosure. The device 2700 includes: a scan module 2710, a reconstruction module 2720, and an imaging module 2730. The MRI device 2700 is implemented on the processing device 140 in software or hardware. The MRI device 2700 is used to perform the processes in FIGS. 19-24.

The scan module 2710 is configured to perform a magnetic resonance scan on an imaging object according to a preset sampling trajectory, and to obtain raw scan data of multiple phases of the imaging object. The raw scan data includes scan data of different slices of the imaging object.

The reconstruction module 2720 is configured to determine a coil sensitivity map based on the raw scan data, and reconstruct the raw scan data of each phase based on the coil sensitivity map to obtain multi-phase scan images of the imaging object.

The imaging module 2730 is configured to perform MRI based on multi-phase scan images.

In some embodiments, the MRI device 2700 further includes a display module. The display module is used to display a magnetic resonance image of the imaging object on a display interface. The magnetic resonance image of the imaging object may be a static image or a dynamic image. The static image may be a reconstructed image of one phase or an averaged reconstructed image of multiple phases. The dynamic image is multi-phase scan images displayed in the order of sampling time.

The processes performed by the modules of the MRI device 2700 are described in detail in FIG. 19-24.

The method involves performing an MRI scan on the imaging object using a preset sampling trajectory to acquire raw scan data of different phases. The raw scan data includes scan data corresponding to different slices of the imaging object. Next, a coil sensitivity map is determined based on the raw scan data for each phase, and the sensitivity map is then used to reconstruct the raw scan data, resulting in multi-phase scan images of the imaging object. Based on the multi-phase scan images, MRI is subsequently performed.

This method, as proposed in the embodiments of the present disclosure, offers several advantages. On one hand, by using a preset sampling trajectory to acquire raw scan data of multiple phases, the method achieves rapid and complete data acquisition that ensures both the completeness required for static imaging and the temporal resolution necessary for dynamic imaging, thus providing a solid data basis for subsequent image reconstruction. On the other hand, by determining the coil sensitivity map and reconstructing the raw scan data based on the sensitivity map, the method enables high-quality image reconstruction and generates multi-phase scan images. These multi-phase scan images can then be used in various imaging modes.

Therefore, by employing the MRI method of the present disclosure, both static high-definition imaging and dynamic high-definition imaging requirements can be simultaneously met in a single scanning process. Moreover, the reconstructed multi-phase scan images are adaptable to multiple imaging modes, enabling the generation of MR images under different imaging scenarios, which not only improves the efficiency of MRI but also enhances the imaging quality to satisfy varied clinical needs.

It should be noted that the foregoing descriptions related to the processes are for the purpose of exemplification and illustration only and do not limit the scope of application of the present disclosure. For those skilled in the art, various corrections and changes may be made to the various processes of the process under the guidance of the present disclosure. However, these corrections and changes remain within the scope of the present disclosure. For example, adding storage operations between processes, etc.

It should be noted that the above descriptions of the systems and their modules are provided only for descriptive convenience, and do not limit the present disclosure to the scope of the cited embodiments. It is to be understood that for those skilled in the art, after understanding the principle of the system, it is possible to arbitrarily combine the modules or form a sub-system to be connected to the other modules without departing from this principle. In some embodiments, the modules are different modules in a system, or a single module implement the functions of two or more of the modules described above. For example, the individual modules may share a common storage module, and the individual modules may each have their own storage module. Morphisms such as these are within the scope of protection of the present disclosure.

The basic concepts have been described above, and it is apparent to those skilled in the art that the foregoing detailed disclosure serves only as an example and does not constitute a limitation of the present disclosure. While not expressly stated herein, various modifications, improvements, and amendments may be made to the present disclosure by those skilled in the art. Those types of modifications, improvements, and amendments are suggested in the present disclosure, so those types of modifications, improvements, and amendments remain within the spirit and scope of the exemplary embodiments of the present disclosure.

Also, the present disclosure uses specific words to describe embodiments thereof. Such as “an embodiment”, “one embodiment”, and/or “some embodiments” means a feature, structure, or characteristic associated with at least one embodiment of the present disclosure. Accordingly, it should be emphasized and noted that “one embodiment”, “an embodiment”, or “an alternative embodiment” referred to two or more times in different positions in the present disclosure do not necessarily refer to the same embodiment. In addition, certain features, structures, or characteristics in one or more embodiments of the present disclosure may be suitably combined.

Additionally, unless expressly stated in the claims, the order of the processing elements, the use of numerical letters, or the use of other names as described in the present disclosure are not intended to qualify the order of the processes and methods of the present disclosure. While some embodiments of the present disclosure that are currently considered useful are discussed in the foregoing disclosure by way of various examples, it should be appreciated that such details serve only illustrative purposes, and that additional claims are not limited to the disclosed embodiments. Rather, the claims are intended to cover all amendments and equivalent combinations that are consistent with the substance and scope of the embodiments of the present disclosure. For example, although the implementation of various components described above are embodied in a hardware device, it may also be implemented as a software only solution, e.g., an installation on an existing server or mobile device.

Similarly, it should be noted that to simplify the presentation of the present disclosure, and thereby aid in the understanding of one or more embodiments of the present disclosure, the foregoing descriptions of embodiments of the present disclosure sometimes group multiple characteristics together in a single embodiment, accompanying drawings, or a description thereof. However, this manner of disclosure does not imply that the objects of the present disclosure require more characteristics than those mentioned in the claims. Rather, claimed subject matter may lie in less than all characteristics of a single foregoing disclosed embodiment.

Some embodiments use numbers to describe the number of components, attributes, and it should be understood that such numbers used in the description of embodiments are modified in some examples by the modifiers “approximately”, “nearly”, or “substantially”. Unless otherwise noted, the terms “nearly,” “substantially,” or “approximately” indicates that a±20% variation in the stated number is allowed. Correspondingly, in some embodiments, the numerical parameters used in the present disclosure and claims are approximations, which changes depending on the desired characteristics of individual embodiments. In some embodiments, the numerical parameters should take into account the specified number of valid digits and employ general place-keeping. While the numerical domains and parameters used to confirm the breadth of their ranges in some embodiments of the present disclosure are approximations, in specific embodiments such values are set to be as precise as practicable.

For each of the patents, patent applications, patent application disclosures, and other materials cited in the present disclosure, such as articles, books, specification sheets, publications, documents, etc., are hereby incorporated by reference in their entirety into the present disclosure. Application history documents that are inconsistent with or conflict with the contents of the present disclosure are excluded, as are documents (currently or hereafter appended to the present disclosure) that limit the broadest scope of the claims of the present disclosure. It should be noted that in the event of any inconsistency or conflict between the descriptions, definitions, and/or use of terms in the materials appended to the present disclosure and those set forth herein, the descriptions, definitions and/or use of terms in the present disclosure shall control.

Finally, it should be understood that the embodiments described in the present disclosure are only used to illustrate the principles of the embodiments of the present disclosure. Other deformations may also fall within the scope of the present disclosure. As such, alternative configurations of embodiments of the present disclosure may be viewed as consistent with the teachings of the present disclosure as an example, not as a limitation. Correspondingly, the embodiments of the present disclosure are not limited to the embodiments expressly presented and described herein.

What is claimed is:

1. A magnetic resonance imaging (MRI) method, comprising:
obtaining at least one first K-space dataset from a plurality of K-space datasets corresponding to a plurality of phases of an imaging object, wherein the at least one first K-space dataset is undersampled, and each of the plurality of K-space datasets corresponds to one of the plurality of phases;
for each of the at least one first K-space dataset, determining a target K-space dataset corresponding to the first K-space dataset by filling, based on at least one second K-space dataset, an undersampled region of the first K-space dataset, wherein the at least one second K-space dataset is from the plurality of K-space datasets and corresponds to a different phase from the first K-space dataset; and
generating a reconstructed image of the imaging object based on the target K-space dataset.

2. The method according to claim 1, wherein at least two first K-space datasets are obtained from the plurality of K-space datasets of the imaging object; and
for each of the at least one first K-space dataset, determining the target K-space dataset corresponding to the first K-space dataset by filling, based on the at least one second K-space dataset, the undersampled region of the first K-space dataset includes:
arranging the at least two first K-space datasets in a preset order;
determining the target K-space dataset corresponding to each of the at least two first K-space datasets by processing, in the preset order, the at least two first K-space datasets.

3. The method according to claim 1, wherein the undersampled region of the first K-space dataset includes a plurality of undersampled sub-regions;
determining the target K-space dataset corresponding to the first K-space dataset by filling, based on the at least one second K-space dataset, the undersampled region of the first K-space dataset includes:
for each of the plurality of undersampled sub-regions,
determining whether there is at least one initial K-space dataset in the at least one second K-space dataset, the initial K-space dataset including an associated sub-region, a K-space position of the associated sub-region corresponding to a K-space position of the undersampled sub-region, and the associated sub-region being fully sampled;
in response to determining that there is at least one initial K-space dataset in the at least one second K-space dataset, determining a reference K-space dataset from the at least one initial K-space dataset; and
filling the undersampled sub-region based on the reference K-space dataset.

4. The method according to claim 3, wherein determining the reference K-space dataset from the at least one initial K-space dataset includes:
determining a phase interval between each of the at least one initial K-space dataset and the first K-space dataset; and
determining the reference K-space dataset based on the phase interval.

5. The method according to claim 3, wherein determining whether there is at least one initial K-space dataset in the at least one second K-space dataset includes:
determining at least one candidate K-space dataset from the at least one second K-space dataset, wherein a phase interval between the at least one candidate K-space dataset and the first K-space dataset is within a preset range; and
determining whether there is at least one initial K-space dataset in the at least one candidate K-space dataset.

6. The method according to claim 3, wherein filling the undersampled sub-region based on the reference K-space dataset includes:
determining a phase interval between the reference K-space dataset and the first K-space dataset;
determining a target weight based on the phase interval between the reference K-space dataset and the first K-space dataset; and
filling the undersampled sub-region based on the target weight and the associated sub-region of the reference K-space dataset.

7. The method according to claim 6, wherein determining the target weight based on the phase interval between the reference K-space dataset and the first K-space dataset includes:
determining the target weight based on the phase interval and a weight correlation table, wherein the weight correlation table includes a correspondence between the target weight and the phase interval.

8. The method according to claim 1, wherein for each of the at least one first K-space dataset, determining the target K-space dataset corresponding to the first K-space dataset by filling, based on the at least one second K-space dataset, the undersampled region of the first K-space dataset includes:
determining the target K-space dataset by sharing K-space data of the at least one second K-space dataset with the unsampled region of the first K-space dataset, a K-space position of the shared K-space data of the at least one second K-space dataset corresponding to a K-space position of the undersampled region of the first K-space dataset.

9. The method according to claim 1, wherein generating the reconstructed image of the imaging object based on the target K-space dataset includes:
obtaining a reconstruction mask, the reconstruction mask characterizing a weight and/or a phase corresponding to the at least one second K-space dataset; and
generating the reconstructed image by reconstructing, using the reconstruction mask, the target K-space dataset.

10. The method according to claim 1, wherein generating a reconstructed image of the imaging object based on the target K-space dataset includes:
obtaining a coil sensitivity map; and
generating the reconstructed image based on the target K-space dataset and the coil sensitivity map.

11. The method according to claim 10, wherein obtaining the coil sensitivity map includes:
determining intermediate scan data by performing weighted averaging on the plurality of K-space datasets and/or the target K-space dataset; and
generating the coil sensitivity map based on the intermediate scan data.

12. The method according to claim 11, wherein the plurality of K-space datasets correspond to at least one slice of the imaging object; and
determining the intermediate scan data by performing weighted averaging on the plurality of K-space datasets and/or the target K-space dataset includes:
determining, from the plurality of K-space datasets and/or the target K-space dataset, the K-space datasets belonging to the same slice;
for each of the at least one slice, determining average scan data for the slice by performing weighted averaging on the K-space datasets of the slice; and
generating the intermediate scan data based on the average scan data for the at least one slice.

13. The method according to claim 10, wherein generating the reconstructed image of the imaging object based on the target K-space dataset includes:
generating an initial image by reconstructing, based on the coil sensitivity map, the target K-space dataset; and
generating a target image by inputting the initial image into a preset reconstruction model for iterative reconstruction processing, the reconstructed image including the target image.

14. The method according to claim 10, wherein
the plurality of K-space datasets are acquired in a preset sampling trajectory;
the preset sampling trajectory is complementary and interlaced in a phase direction;
for the preset sampling trajectory, an acceleration factor in a central region of K-space is less than a first threshold, and an acceleration factor in a non-central region of K-space is greater than a second threshold; and
the first threshold is less than or equal to the second threshold.

15. The method according to claim 1, wherein the reconstructed image includes a plurality of target images each of which corresponds to one of the plurality of phases, the method further comprising:
obtaining an MRI mode;
determining a target display image by processing, based on the MRI mode, the plurality of target images; and
displaying the target display image.

16. The method according to claim 15, wherein in response to determining that the MRI mode includes a static imaging mode, determining the target display image by processing, based on the MRI mode, the plurality of target images includes:
selecting one of the plurality of target images corresponding to any phase as the target display image; or
selecting one of the plurality of target images that satisfies a preset image quality requirements.

17. The method according to claim 15, wherein in response to determining that the MRI mode includes a high-definition imaging mode, determining the target display image by processing, based on the MRI mode, the plurality of target images includes:
generating an average scan image by performing averaging on the plurality of target images; and
using the average scan image as the target display image.

18. A magnetic resonance imaging (MRI) method, comprising:
obtaining at least one first K-space dataset from a plurality of K-space datasets corresponding to a plurality of phases of an imaging object, wherein the at least one first K-space dataset is undersampled, and each of the plurality of K-space datasets corresponds to one of the plurality of phases;
for each of the at least one first K-space dataset, determining a target K-space dataset by sharing K-space data of at least one of K-space datasets other than the first K-space dataset in the plurality of K-space datasets;
obtaining a reconstruction mask, the reconstruction mask characterizing a weight and/or a phase corresponding to the reused K-space data of the at least one second K-space dataset; and
generating a reconstructed image of the imaging object based on the reconstruction mask and the target K-space dataset.

19. The method according to claim 18, wherein
K-space of the first K-space dataset includes a sampled region and an unsampled region; and
the determining a target K-space dataset by sharing K-space data of at least one of K-space datasets other than the first K-space dataset in the plurality of K-space datasets includes:
sharing the K-space data of the at least one of K-space datasets other than the first K-space dataset in the plurality of K-space datasets with the unsampled region of the first K-space dataset, a K-space position of the shared K-space data of the at least one of K-space datasets other than the first K-space dataset in the plurality of K-space datasets corresponding to a K-space position of the unsampled region of the first K-space dataset.

20. A system, comprising:
at least one storage device including a set of instructions; and
at least one processor in communication with the at least one storage device, wherein when executing the set of instructions, the at least one processor is directed to perform operations including:
obtaining at least one first K-space dataset from a plurality of K-space datasets corresponding to a plurality of phases of an imaging object, wherein the at least one first K-space dataset is undersampled, and each of the plurality of K-space datasets corresponds to one of the plurality of phases;
for each of the at least one first K-space dataset, determining a target K-space dataset corresponding to the first K-space dataset by filling, based on at least one second K-space dataset, an undersampled region of the first K-space dataset, wherein the at least one second K-space dataset is from the plurality of K-space datasets and corresponds to a different phase from the first K-space dataset; and
generating a reconstructed image of the imaging object based on the target K-space dataset.
